(19) United States
(12) Patent Application Publication
(10) Pub. No.: US 2026/0113142 A1
(43) Pub. Date: Apr. 23, 2026

(54) INTERLEAVER AND DEINTERLEAVER WITH DELAY MEMORY FOR A TRANSMITTER OR RECEIVER

(71) Applicant: NORTHROP GRUMMAN SYSTEMS CORPORATION, FALLS CHURCH, VA (US)

(72) Inventor: RONALD P. SMITH, Manhattan Beach, CA (US)

(21) Appl. No.: 18/603,397

(22) Filed: Mar. 13, 2024

(51) Int. Cl. H04L 1/00

(52) U.S. Cl. CPC H04L 1/0016; H04L 1/0057; H04L 1/0061; H04L 1/0071

(57) ABSTRACT

A wireless transceiver with an interleaver receives an input data stream having codewords formed by a combination of input data and error correction codes. The interleaver includes a delay memory with a write interface and a read interface an ingress module that reorders the input data stream to at an interleaver size and rate that satisfies a write threshold that defines a portion of the predetermined size and rate of the delay memory. The interleaver also includes an egress module that outputs an interleaved data stream and a memory controller that controls operations of the delay memory. The memory controller causes the delay memory to store the data words of the ingress stream as blocks of data with a set number of rows, rearranging the data words in a predefined and reversible pattern. The wireless transceiver further includes a wireless transmitter that transmits the interleaved data stream into free space.

### TECHNICAL FIELD

This disclosure relates to a transmitter or receiver. More particularly, this disclosure relates to a transmitter or receiver with an interleaver or a deinterleaver with delay memory.

### BACKGROUND

An interleaver is a component in digital communication systems, designed to enhance data transmission reliability by rearranging the order of a sequence of symbols, such as bits. This rearrangement curtails the impact of burst errors, which occur in clusters, by spreading out the data bits. Consequently, these dispersed bits, when affected by burst errors, allow error correction techniques to work more efficiently. After transmission, a deinterleaver restores the data to its original order. Interleavers are especially used in environments prone to signal interference, such as in satellite and wireless communications, striking a balance between error management effectiveness and the complexity of the system.

A block interleaver is a digital communication technique used to protect data against burst errors by rearranging the symbols within fixed-size blocks. A block interleaver works by writing the data into a matrix row-by-row and then reading the data out in a different pattern, like column-by-column, effectively spreading the bits across the block. This dispersal reduces the impact of burst errors, which tend to affect contiguous bits. At the receiving end, a deinterleaver with an inverse structure restores the data to its original order. Block interleavers are particularly useful in systems where data is transmitted in fixed-size packets or frames, such as in digital television and certain wireless communication protocols, due to their simplicity and effectiveness in enhancing error correction.

A convolutional interleaver is a type of interleaver used in digital communication to disperse burst errors across a data stream. Unlike block interleavers that work on fixed-size data blocks, convolutional interleavers handle continuous data streams by feeding input symbols into a series of shift registers, each delaying the input by different amounts. This process spreads the symbols in time, reducing the impact of burst errors on consecutive symbols. A corresponding convolutional deinterleaver at the destination reverses these delays, restoring the original data order for effective error correction. This makes convolutional interleavers useful for real-time and high-speed data transmission in environments prone to burst errors, such as in satellite and cellular communications.

### SUMMARY

A first example is related to a wireless transceiver that includes an interleaver that receives an input data stream including codewords formed of a combination of input data and error correction codes. The interleaver includes delay memory with a write interface tuned to receive data words at a write interface that have a predetermined size and rate and a read interface tuned to provides data words at the predetermined size and rate and an ingress module that reorders the input data stream to provide an ingress stream of data words to the write interface of the delay memory at an interleaver size and rate that satisfies an interleaver write threshold that defines a portion of the predetermined size and rate of the delay memory of the interleaver. The interleaver includes an egress module that receives an egress stream of data words from the delay memory at an interleaver size and rate that satisfies an interleaver read threshold that defines a portion of the predetermined size and rate of the delay memory of the interleaver and outputs an interleaved data stream. The interleaver also includes a memory controller that controls operations of the delay memory. The memory controller causes the delay memory to store the data words of the ingress stream of data words received at the write interface as blocks of data in the delay memory. The blocks of data include a set number of rows, and the data words received at the write interface of the delay memory are rearranged in a predefined and reversible pattern, such that data words of the egress stream of data words provided at the read interface of the delay memory have a different order than the data words of the ingress stream of data words received at the write interface of the delay memory. The wireless transceiver also includes a wireless transmitter that transmits the interleaved data stream received from the egress module into free space.

A second example relates to a system for wirelessly transmitting data over a link. The system includes a first transceiver including an error correction inserter that inserts error correction codes into a stream of input data to provide a stream of codewords including a combination of data in the stream of input data and the error correction codes and an interleaver that receives the stream of codewords. The interleaver includes delay memory with a write interface tuned to receive data words at a write interface that have a predetermined size and rate and a read interface tuned to provides data words at the predetermined size and rate. The interleaver includes an ingress module that reorders the stream of codewords to provide a first ingress stream of data words to the write interface of the delay memory of the interleaver at an interleaver size and rate that satisfies an interleaver write threshold that defines a portion of the predetermined size and rate of the delay memory of the interleaver. The interleaver also includes an egress module that receives a first egress stream of data words from the delay memory of the interleaver at an interleaver size and rate that satisfies an interleaver read threshold that defines a portion of the predetermined size and rate of the delay memory of the interleaver and outputs an interleaved data stream. The interleaver further includes a memory controller that controls operations of the delay memory of the interleaver. The memory controller causes the delay memory to store the data words of the first ingress stream of data words received at the write interface as blocks of data in the delay memory of the interleaver, the blocks of data including a set number of rows and the data words of the first ingress stream of data words received at the write interface of the delay memory are rearranged in a predefined and reversible pattern, such that data words of the first egress stream of data words provided at the read interface of the delay memory have a different order than the data words of the first ingress stream of data words received at the write interface of the delay memory. The first transceiver also includes a wireless transmitter that transmits the interleaved data stream received from the egress module over the link. The system includes a second transceiver with a wireless receiver that receives the interleaved data stream transmitted over the link and a deinterleaver that receives the interleaved data stream from the wireless receiver. The deinterleaver includes delay memory with a write interface tuned to receive data words at the predetermined size and rate and a read interface tuned to provide data words at the predetermined size and rate and an ingress module that reorders the interleaved data stream to provide a second ingress stream of data words based on the interleaved data stream to the write interface of the delay memory of the deinterleaver at a deinterleaver size and rate that satisfies a deinterleaver write threshold that defines a portion of the predetermined size and rate of the delay memory of the deinterleaver. The deinterleaver includes an egress module that receives a second egress stream of data words from the delay memory of the deinterleaver at a deinterleaver size and rate that satisfies a deinterleaver read threshold that defines a portion of the predetermined size and rate of the delay memory of the deinterleaver and outputs a deinterleaved data stream having codewords including data and error correction codes based on the second egress stream of data words and a memory controller that controls operations of the delay memory of the deinterleaver. The memory controller causes the delay memory of the deinterleaver to store the data words of the second ingress stream of data words received at the write interface as blocks of data. The blocks of data include the set number of rows, and the data words received at the write interface of the delay memory of the deinterleaver are rearranged to reverse the predefined and reversible pattern, such that data words of the second egress stream of data words provided at the read interface of the delay memory of the deinterleaver have a different order than data words of the second ingress stream of data words received at the write interface of the delay memory of the deinterleaver. The second transceiver also includes an error corrector that detects and corrects errors in the deinterleaved data stream based on the error correction codes of the deinterleaved data stream to provide a stream of output data, such that the stream of output data matches the stream of input data.

A third example relates to a method for wirelessly communicating data over a data link. The method including receiving, by an interleaver, an input data stream including codewords formed with a combination of input data and error correction codes and reordering, by an ingress module of the interleaver, the input data stream to provide an ingress stream of data words to a write interface of delay memory of the interleaver at an interleaver size and rate that satisfies an interleaver write threshold that defines a portion of a predetermined size and rate for the delay memory of the interleaver. The method include controlling, by a controller of the interleaver, operations of the delay memory, to cause the delay memory to store the data words of the ingress stream of data words received at the write interface as blocks of data in the delay memory. The blocks of data includes a set number of rows, and the data words received at the write interface of the delay memory are rearranged in a predefined and reversible pattern to provide an egress stream of data words at an read interface of the delay memory that have a different order than the data words of the ingress stream of data words received at the write interface of the delay memory. The method also includes receiving, at an egress module of the interleaver, an egress stream of data words from the delay memory at an interleaver size and rate that satisfies an interleaver read threshold that defines a portion of the predetermined size and rate of the delay memory of the interleaver and outputs an interleaved data stream. The method further includes reordering, by an egress module of the interleaver, the egress stream of data words to provide an interleaved data stream and transmitting, by a transmitter, the interleaved data stream received from the egress module into free space.

### BRIEF DESCRIPTION OF THE DRAWINGS

FIG. 1 illustrates a communication system that includes a first transceiver and a second transceiver.

FIG. 2A illustrates operations of a convolutional interleaver.

FIG. 2B illustrates operations of a convolutional deinterleaver.

FIG. 3A illustrates an example of a block interleaver.

FIG. 3B illustrates operations of a block deinterleaver.

FIG. 4 illustrates a block diagram of a data rearranger that is employable to implement an interleaver or a deinterleaver.

FIG. 5 illustrates an example of a serial to parallel interface.

FIG. 6 illustrates an example of an ingress symbol buffer.

FIG. 7 illustrates an example of an ingress reorder symbols submodule.

FIG. 8 illustrates an example of an ingress word buffer.

FIG. 9A illustrates a delay memory convolutional interleaver.

FIG. 9B illustrates a delay memory convolutional deinterleaver.

FIG. 10A illustrates a delay memory block interleaver.

FIG. 10B illustrates a delay memory block deinterleaver.

FIG. 11 illustrates an example of an egress word buffer.

FIG. 12 illustrates an example of an egress reorder symbols submodule.

FIG. 13 illustrates an example of an egress symbol buffer.

FIG. 14 illustrates an example of a parallel to serial interface.

FIG. 15 illustrates a flowchart of an example method for wirelessly communicating data over a data link.

### DETAILED DESCRIPTION

This description relates to a system, such as a communication system with two transceivers capable of bi-directional wireless communication through a free space link. These transceivers are similarly designed. The two transceivers function by receiving input data from an external source (such as a computer), processing the data to form interleaving data, and then transmitting the interleaved data over a free space data link.

In one implementation, these transceivers are situated in different terrestrial locations, such as separate buildings, and use optical components (e.g., lasers and photodetectors) to establish a free space optical link. In another scenario, one transceiver is positioned in a terrestrial facility and the other on an orbiting satellite. Here, the two transceivers can use either optical components or radio frequency transmitters and receivers, creating an earth-to-satellite link.

One challenge in this system is channel fading, which occurs in the free space link. This fading leads to variations in signal strength due to environmental factors like multipath interference, path loss, shadowing and Doppler fading, causing problems like rapid changes in signal strength, connection losses and data transmission errors. To combat these issues, both transceivers incorporate error correction codes (ECCs) into the incoming data. Each transceiver has a component that inserts error correction codes into the data stream to provide a stream of codewords that include input data and the error correction codes.

However, due to the nature of channel fading, certain intervals of data (e.g., bursts of data) are impacted more than other intervals. To curtail the impact of the channel fading, an interleaver in each transceiver rearranges the codewords, enhancing error correction capabilities and reducing the impact of burst errors. An interleaved data stream (e.g., a rearranged data stream) is then transmitted over the free space link. Upon reception, a deinterleaver in each transceiver reverses this bit rearrangement process, producing deinterleaved codewords that might still contain errors due to factors like channel fading. An error corrector in each transceiver then detects and corrects these errors, reconstructing the original input data. The interleaving process, combined with the embedded ECCs, enables more effective error correction, enhancing the overall reliability of the communication system.

Both the interleaver and deinterleaver are equipped with integrated circuit chips and include a delay memory, such as SDRAM (Synchronous dynamic random-access memory), with a significant storage capacity, such as 1 GB (gigabyte) or more (e.g., 8 GB). This delay memory is tuned for efficiency in data transfer, considering factors like burst size and read/write block size. To ensure the efficiency of data transfer, the interleaver and deinterleaver feature ingress and egress modules that organize data for efficient transfer through the delay memory. These modules ensure data is read and written at some portion (e.g., about 50% or more) of predetermined sizes and rates of the delay memory, maintaining a high throughput.

In various examples, the interleavers/deinterleavers are implemented with convolutional interleavers/deinterleavers or block interleavers/deinterleavers. The interleaver/deinterleaver described in the present description effectively manages data transmission across the free space link. In particular, by rearranging data with interleavers and deinterleavers, the system distributes data loss due to channel fades across multiple blocks, reducing the impact of channel fading and enhancing error correction. Moreover, this design ensures high throughput rates for large memory modules (e.g., the delay memory), curtailing bottlenecks and maintaining efficient operation.

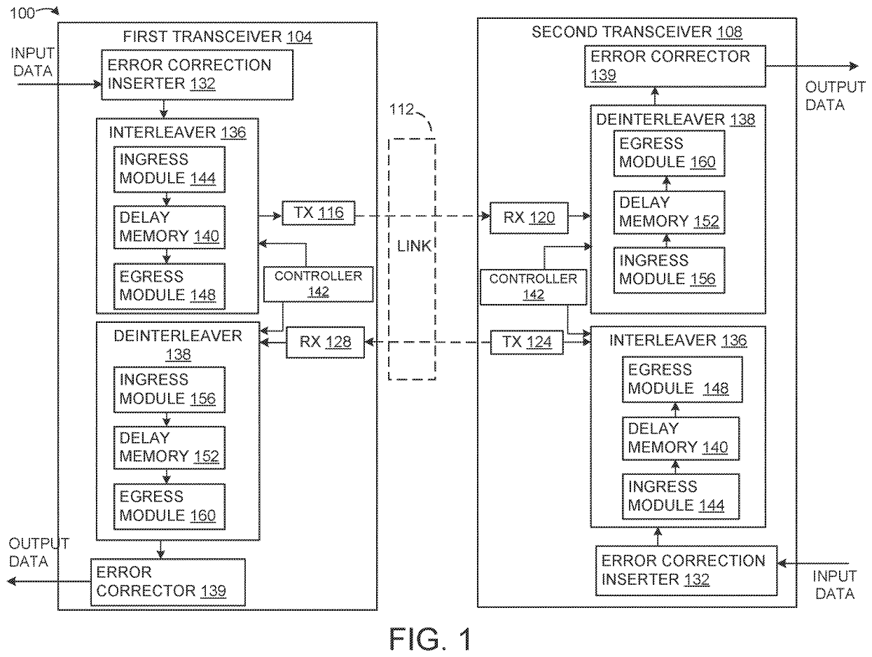

FIG. 1 illustrates a communication system 100 that includes a first transceiver 104 and a second transceiver 108. The first transceiver 104 and the second transceiver 108 wirelessly communicate over a free space link 112. The first transceiver 104 includes a transmitter 116 that provides a signal through the free space link 112 to a receiver 120 of the second transceiver 108. Similarly, the second transceiver 108 includes a transmitter 124 that provides a signal through the free space link 112 to a receiver 128 of the first transceiver 104. In this way, the first transceiver 104 and the second transceiver 108 have bi-directional communication.

The first transceiver 104 and the second transceiver 108 are implemented with similar features. Thus, for purposes of simplification, the same reference numbers are used in the first transceiver 104 and the second transceiver 108 to describe different instances of the same device (e.g., a device that operates in the same or similar manner).

In operation, the first transceiver 104 receives input data (labeled “INPUT DATA”) that is provided from an external source (e.g., a computer). This input data is processed, augmented and modulated for transmission and transmitted by the transmitter 116 on the free space link 112 to the receiver 120 of the second transceiver 108, and the second transceiver 108 provides output data (labeled “OUTPUT DATA”) to an external system (e.g., a computer). Conversely, the second transceiver 108 receives input data (labeled “INPUT DATA”) that is provided from an external source (e.g., a computer). This input data is processed, augmented and modulated for transmission and transmitted by the transmitter 124 on the free space link 112 to the receiver 128 of the first transceiver 104, and the first transceiver 104 provides output data (labeled “OUTPUT DATA”) to an external source (e.g., a computer).

In one example, the first transceiver 104 is installed in a first terrestrial location (e.g., a first building) and the second transceiver 108 is installed in a second terrestrial location (e.g., a second building). In this example, the transmitter 116 of the first transceiver 104 and the transmitter 124 of the second transceiver 108 are optical transmitters (e.g., lasers), and the receiver 120 of the second transceiver 108 and the receiver 128 of the first transceiver 104 are optical receivers, such as photoreceivers or photodetectors. Thus, the free space link 112 provides a free space optical (FSO) link between the first transceiver 104 and the second transceiver 108 in this example.

In another example, the first transceiver 104 is installed in a terrestrial facility (e.g., a satellite communication point) and the second transceiver 108 is installed on an in-orbit satellite. In this situation, the transmitter 116 of the first transceiver 104 and the transmitter 124 of the second transceiver 108 are optical transmitters (e.g., telescopes) or radio frequency (RF) transmitters (e.g., antennas), and the receiver 120 of the second transceiver 108 and the receiver 128 of the first transceiver 104 are optical receivers or RF receivers (e.g., antennas). Thus, the free space link 112 provides an earth to satellite link. Additionally, in situations where the first transceiver 104 and the second transceiver 108 communicate with RF signals, the transmitter 116 and the receiver 128 can be integrated as a first terminal and the receiver 120 and the transmitter 124 can be integrated and implemented as a second terminal.

In any such example, the free space link 112 has channel fading. Fading channels in wireless communication, such as the free space link 112 are characterized by variations in signal strength, caused by environmental factors including atmospheric variations such as changing concentration of water vapor which changes a signal loss. Additionally, in some examples, fading channels can be caused by multipath interference, where the signal reaches the receiver through various paths causing constructive and destructive interference. This multipath interference leads to rapid signal fluctuations (fast fading). Other factors include path loss due to increased distance, shadowing from obstacles like buildings and Doppler fading from relative motion between the transmitter and receiver. These variations can significantly impact the signal quality, leading to issues like rapid changes in signal strength, connection losses and data transmission errors.

To combat the effects of channel fading, error correction codes (ECCs) are inserted in the input data received by the first transceiver 104 and the second transceiver 108. More specifically, the first transceiver 104 and the second transceiver 108 include an error correction inserter 132 that inserts ECCs into the received input data. The input data of both the first transceiver 104 and the second transceiver 108 is a stream of data, such as packets of data. The error correction inserter 132 of the first transceiver 104 and the second transceiver 108 outputs codewords formed of original data from the input data and redundant bits employable for error detection and correction. The error correction inserter 132 of the first transceiver 104 and the second transceiver 108 provide the codewords to an interleaver 136. More particularly, the error correction inserter 132 of the first transceiver 104 provides a first stream of codewords to the interleaver 136 of the first transceiver 104, and the error correction inserter 132 of the second transceiver 108 provides a second stream of codewords to the interleaver 136 of the second transceiver 108.

The interleaver 136 of the first transceiver 104 and the second transceiver 108 rearranges the order of bits in the codewords to improve error correction and reduce the impact of burst errors. Stated differently, the interleaver 136 of the first transceiver 104 scrambles the first stream of codewords in a predefined and reversible pattern that disperses the bits of the codewords across a wider span of a transmitted signal. Similarly, the interleaver 136 of the second transceiver 108 scrambles the second stream of codewords in the predefined and reversible pattern. This rearrangement makes the input data (of the first transceiver 104 and the second transceiver 108) more resistant to burst errors, which are errors concentrated (or combined in a different manner) in a specific part of the signal, often caused by temporary disturbances such as noise or channel fading. The interleaver 136 outputs an interleaved data stream that has a predefined and reversible pattern. In the first transceiver 104, the interleaver 136 provides a first interleaved data stream to the transmitter 116, which in turn transmits the first interleaved data stream over the free space link 112 and to the receiver 120. Similarly, in the second transceiver 108, the interleaver 136 provides a second interleaved data stream to the transmitter 124, which in turn transmits the second interleaved data stream to the receiver 128 of the first transceiver 104 over the free space link 112.

Additionally, the first transceiver 104 and the second transceiver 108 include a deinterleaver 138 that receives an interleaved data stream from a corresponding receiver, namely the receiver 128 of the first transceiver 104 and the receiver 120 of the second transceiver 108. Stated differently, the receiver 128 provides the second interleaved data stream to the deinterleaver 138 of the first transceiver 104, and the receiver 120 provides the deinterleaver 138 of the second transceiver 108 with the first interleaved data stream. The deinterleaver 138 reorders the bits of the interleaved data to reverse the rearrangement of the interleaving executed by the interleaver 136. Thus, the deinterleaver 138 outputs deinterleaved codewords. More specifically, the deinterleaver 138 of the first transceiver 104 outputs a first stream of deinterleaved codewords that correspond to the second stream of codewords (output by the error correction inserter 132 of the second transceiver 108). Similarly, the deinterleaver 138 of the second transceiver 108 outputs a second stream of deinterleaved codewords that correspond to the first stream of codewords (output by the error correction inserter 132 of the first transceiver 104). The first stream of deinterleaved codewords and the second stream of deinterleaved codewords may have errors caused by channel fading of the free space link 112 and/or for other reasons.

The first transceiver 104 and the second transceiver 108 include an error corrector 139. The error corrector 139 detects errors in a stream of deinterleaved codewords to reconstruct input data provided to a corresponding transceiver of the communication system 100. More specifically, the error corrector 139 of the second transceiver 108 employs ECCs embedded in the second stream of codewords to reconstruct the input data provided to the first transceiver 104. Similarly, the error corrector 139 of the first transceiver 104 employs ECCs embedded in the first stream of codewords to reconstruct the input data provided to the second transceiver 108.

By spreading out errors with the interleaver 136, the ECCs embedded in the first stream of codewords and the second stream of codewords can be leveraged to more effectively correct the errors, enhancing the overall reliability of the communication system 100.

The interleaver 136 is formed with IC (integrated circuit) chips. Moreover, the interleaver 136 includes a delay memory 140, such as SDRAM (synchronous dynamic random-access memory). The delay memory 140 can be formed of an IC chip (or multiple IC chips) to provide a storage capacity sufficient for the desired interleaver, for example, 8 GB (equivalent to 64 Gb (Gigabits) or 2^{\hat{ }36}=68719476736 bits) of storage. The delay memory 140, depending on the type of IC chip used, has a choice of data burst sizes that, along with the interface bit width, defines a number of bits in each data word transferred in one continuous operation following a single command (for example, writing data to a particular burst start address). The delay memory 140 also includes a choice of read or write block size, which defines a number of data bursts used for the data transfer to or from the delay memory 140. The read or write block size can often be configured in a controller 142 (e.g., a memory controller) according to the specific needs of the system (for example, writing 4 data bursts to 4 different burst start addresses). A block size of 1 burst would mean that each memory access of the delay memory 140 transfers a single data word, while a block size of 8 bursts would transfer 8 data words. In some examples, the delay memory 140, can include more efficient data transfers for larger choices of interface bits, data burst size and block size, and those choices are selected in a design to meet the required data rate capability.

In some examples for the delay memory 140, the interface width is 64 bits, and the minimum efficient data burst size is 8, resulting in 512 bits per data burst, and a minimum efficient read or write block size of 4, such that a total transfer of 2048 bits (wherein the data transfer size can be described as a block of S symbols, more generally, as described herein) are written to or read from the delay memory 140 at a time to ensure efficient data transfer. In other examples, there could be more or less bits in the minimum efficient data burst size and/or the minimum efficient read or write block size.

In a first example (hereinafter, “the first example”), the interleaver 136 of the first transceiver 104 and the second transceiver 108 are convolutional interleavers. Additionally, in the first example, the deinterleaver 138 of the first transceiver 104 and the second transceiver 108 are convolutional deinterleavers.

In the first example, the interleaver 136 is programmed with a configurable parameters, ‘N’, representing a number of interleaving rows, and ‘B’ defining a delay factor. The size of memory used for the delay memory 140 of the interleaver 136 is determined by the values of N and B. Moreover, the delay factor, B is measured in symbols (where there may be one or more bits per symbol). Equation 1 defines a relationship between the number of interleaving rows, N, the delay factor, B and the size of the delay memory 140.

$$B ( N - 1 ) * \frac{N}{2} \leq Size \qquad Equation 1$$

Wherein:
   B is the delay factor, in symbols;
   N is the number of interleaving rows; and
   Size it the size, in symbols of delay memory (e.g., the delay memory 140) of an interleaver.

In the first example, it is presumed that the delay memory 140 is 8 GB (e.g., 64 Gb, about 6.87×10¹⁰ bits), the number of interleaving rows, N is equal to 4096 and the delay factor, B is equal to 8192 one-bit symbols. In other examples, other values that comply with Equation 1 for the number of interleaving rows, N and the delay factor, B are employable.

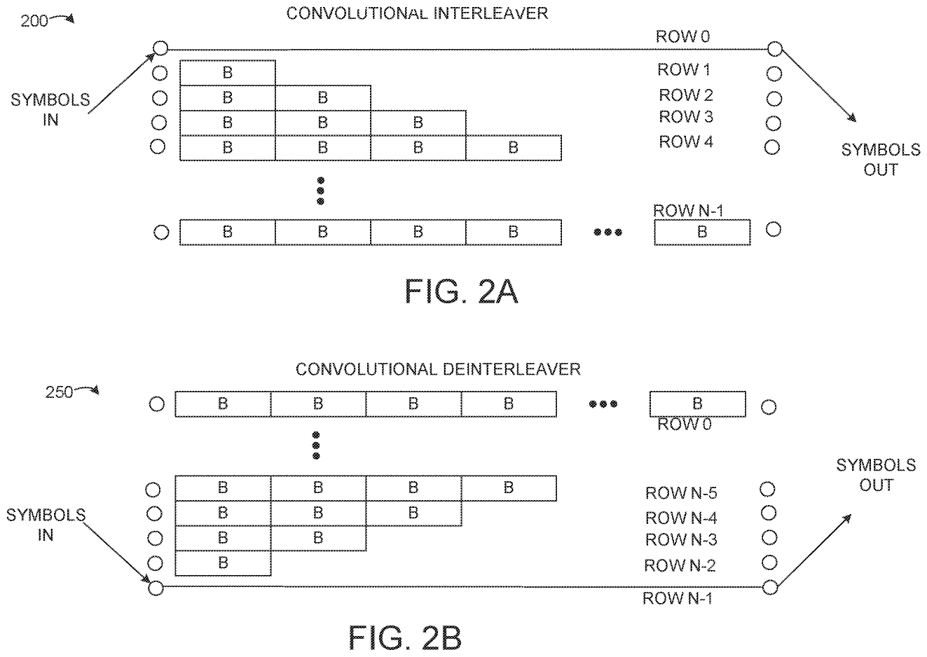

FIG. 2A illustrates operations of a convolutional interleaver 200, such as the interleaver 136 of FIG. 1 in the first example. The convolutional interleaver 200 receives input symbols (e.g., one or more bits, labeled “SYMBOLS IN”) and provides output symbols (labeled “SYMBOLS OUT”).

As noted, in the first example, the number of interleaving rows, N is set to 4096 and the delay factor, B is set to 8192 one-bit symbols. However, for simplification and illustrative purposes, the convolutional interleaver 200, N is set to 6, and B is set to 2. The convolutional interleaver 200 can be analogized as a set of shift registers with different lengths, wherein each shift register represents an interleaver row. Each incoming symbol is placed in a different shift register, and these registers delay the bits by different amounts.

As noted, in the simplified example, there are 6 interleaving rows, rows 0 to row N−1 (row 5). Row 0 has a delay of zero (no delay), row 1 has a delay of 2 (1*B, with B=2), row 2 has a delay of 4 (2*B), and this continues to row 5, which has a delay of 10 (5*B). In this manner, for conceptional purposes, each row has B*N slots, and each slot holds a symbol. Each slot is represented by an index number, iBⱼ where i is a given delay number in a row, and j represents a particular slot within the given delay number. Accordingly, in the simplified example row 0 has 0 slots, (written straight through), row 1 has 2 slots (because row 1 has a 1*B delay), namely slot 1B₀ and slot 1B₁. Additionally, the convolutional interleaver 200 is described such that each timeslot, Time 0 . . . Time 7, includes a write operation and a read operation on a particular row. Additionally, for each such row, the read operation reads from a slot that is one slot higher than the slot written to in the same timeslot, except for row 0, which has no delay. Thus, during a timeslot where the slot of row 1, 1B₀ is written to, the convolutional interleaver 200 reads the slot of row 1, 1B₁.

Now suppose that the input symbols (SYMBOLS IN) are represented as a stream of alphabetic symbols ABCDEFGHIJKLMNOP, where each alphabetic symbol represents a value of one or more bits. In this scenario, the stream of alphabetic symbols would be written through the convolutional interleaver 200 in multiple write-through cycles.

In the through cycle, the symbols, ABCDEFGHIJKLMNOP of the stream of alphabetic symbols are written to the convolutional interleaver 200. More specifically, the first write-through cycle would have 7 timeslots, Time 0 . . . Time 7, which are as follows:
Time 0: Input=A, Output=A (write to row 0, read from row 0)
Time 1: Input=B, Output=x (write to row 1, slot 1B₀, read from row 1, slot 1B₁)
Time 2: Input=C, Output=x (write to row 2, slot 1B₀, read from row 2, slot 1B₁)
Time 3: Input=D, Output=x (write to row 3, slot 1B₀, read from row 3, slot 1B₁))
Time 4: Input=E, Output=x (write to row 4, slot 1B₀, read from row 4, slot 1B₁))
Time 5: Input=F, Output=x (write to row 5, slot 1B₀, read from row 5, slot 1B₁)
Time 6: Input=G, Output=G (write to row 0, read from row 0)
Time 7: Input=H, Output=B (write to row 1, slot 1B₁, read from row 1, slot 1B₀)
Time 8: Input=I, Output=x (write to row 2, slot 1B₁, read from row 2, slot 2B₀)
Time 9: Input=J, Output=x (write to row 3, slot 1B₁, read from row 3, slot 2B₀)
Time 9: Input=K, Output=x (write to row 4, slot 1B₁, read from row 4, slot 2B₀)
Time 10: Input=L, Output=x (write to row 5, slot 1B₁, read from row 5, slot 2B₀)
Time 11: Input=M, Output=M (write to row 0, read from row 0)
Time 12: Input=N, Output=H (write to row 1, slot 1B₀, read from row 1, slot 1B₁)
Time 13: Input=O, Output=x (write to row 2, slot 2B₀, read from row 2, slot 2B₁)
Time 14: Input=P, Output=x (write to row 3, slot 2B₀, read from row 3, slot 2B₁)
Wherein: ‘x’ indicates an unknown value (a previous value stored in the convolutional interleaver 200).

At the end of Time 14 of the first cycle, the output sequence is: AxxxxxGBxxxxMHxx. This trend continues, as each input symbol is read out as an output symbol in a reversible pattern. Moreover, as demonstrated, the sequence of the input symbols is different than the sequence of the output symbols.

FIG. 2B illustrates operations of a convolutional deinterleaver 250, such as the deinterleaver 138 of FIG. 1 in the first example. The convolutional deinterleaver 250 receives input symbols (e.g., one or more bits, labeled “SYMBOLS IN”) and provides output symbols (labeled “SYMBOLS OUT”). Conceptually, the convolutional deinterleaver 250 is a mirror image of the convolutional interleaver 200 of FIG. 2A.

As noted, in the first example, the number of interleaving rows, N is set to 4096 and the delay factor, B is set to 8192 one-bit symbols. However, for simplification and illustrative purposes, for the convolutional deinterleaver 250, N is set to 6, and B is set to 2. In the convolutional deinterleaver 250, row 0 has a delay of 10 (5*B) and row 6 (row N−1) has a delay of 0. That is, in contrast to the convolutional interleaver 200, in the convolutional deinterleaver 250, the delay decreases for each row so as to reverse the interleaving of the convolutional interleaver 200 of FIG. 2A. Thus, the output symbols of the convolutional deinterleaver 250 match an order of the input symbols of the convolutional interleaver 200 of FIG. 2A. However, to achieve this, the symbols are reordered by the convolutional deinterleaver 250, such that the input symbols of the convolutional deinterleaver 250 are in a different sequence than the output symbols of the convolutional deinterleaver 250.

Referring back to FIG. 1, in a second example (hereinafter, “the second example”), the interleaver 136 is implemented with a block interleaver and the deinterleaver 138 is implemented with a block deinterleaver. In the second example, the interleaver 136 is programmed with a configurable parameters, ‘N’, representing a number of interleaving rows, and ‘M’ defining a number of columns of the interleaver 136 and the deinterleaver 138.

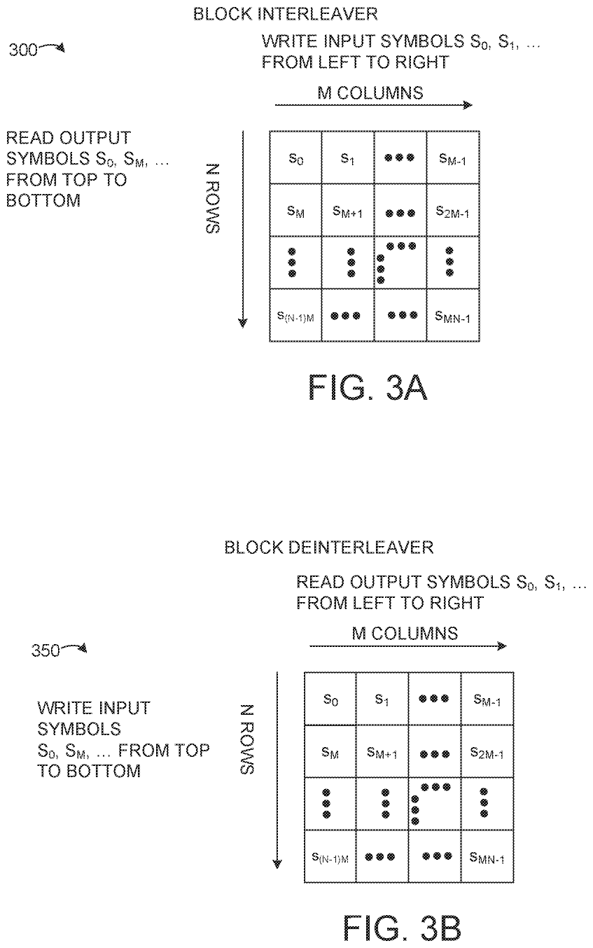

FIG. 3A illustrates an example of a block interleaver 300 that is employable to implement the interleaver 136 of FIG. 1 in the second example. The block interleaver 300 receives a stream of input symbols (one or more bits), such as the codewords received from the error correction inserter 132 of FIG. 1. In response to the codewords, the block interleaver writes the input symbols in the manner illustrated. In particular, in each row, there are M number of symbols written (e.g., symbols S₀ . . . S_{M-1} for row 0) for M number of columns. Moreover, this pattern is executed until the block interleaver 300 is filled for the N number of rows.

The block interleaver 300 also provides a stream of output symbols. The output symbols are provided as columns. Stated differently, for each of the M number of columns, there are N number of rows. The stream of output symbols are reordered (relative to the stream of input symbols) such that one symbol from each row of a given column is output. For example, for column 0, symbols S₀, S_{M}, S_{2M} . . . S_{(N-1)M} are output in sequence. Similarly, advancing to column 1, symbols S₁, S_{M+1}, S_{2M+2} . . . S_{(N-1)M+1} are output next.

FIG. 3B illustrates operations of a block deinterleaver 350, such as the deinterleaver 138 of FIG. 1 in the first example. The block deinterleaver 350 receives input symbols and provides output symbols. Conceptually, the block deinterleaver 350 has a same format as the block interleaver 300 of FIG. 3A.

More particularly, for filling the block deinterleaver 350, the input symbols are written as columns 0 . . . M−1, with each column having N number of symbols stored therein. Accordingly, column 0 stores the input symbols S₀, S_{M}, S_{2M} . . . S_{(N-1)M} in sequence. Similarly, advancing to column 1, symbols S₁, S_{M+1}, S_{2M+2} . . . S_{(N-1)M+1} are stored next. The block deinterleaver 350 provides a stream of output symbols that are read as rows of the block deinterleaver 350. Specifically, the stream of output symbols has a sequence of S₀, S₁, S₂ . . . S_{M-1} for row 0, and the stream of output symbols continues to S_{M}, S_{M+1}, S_{M+2} . . . S_{2M-1} for row 1. Thus, the stream of output symbols of the block deinterleaver 350 matches a sequence of the stream of input symbols of the block interleaver 300 of FIG. 3A. However, to achieve this, the symbols are reordered by the block deinterleaver 350, such that the input symbols of the block deinterleaver 350 are in a different sequence than the output symbols of the block deinterleaver 350.

Referring back to FIG. 1, the delay memory 140 has a write interface (e.g., an input interface) and a read interface (e.g., an output interface) tuned to transfer (receive and provide) data words at a predetermined size and rate. To ensure that the delay memory 140 reads and writes data in the predetermined size and rate (or some portion thereof) that ensure efficient data transfer speeds, the interleaver 136 of the first transceiver 104 and the second transceiver 108 include an ingress module 144 and an egress module 148. The ingress module 144 receives the codewords from the error correction inserter 132 and reorganizes the codewords into a format that is written to the delay memory 140 to achieve the efficient data transfer speeds. Stated differently, the ingress module 144 reorders an input data stream, namely, the codewords, to provide data words to the write interface of the delay memory 140 at an interleaver size and rate that satisfies a write threshold of the interleaver 136. The write threshold of the interleaver 136 defines a portion (e.g., 50% or more) of the predetermined size and rate of the delay memory 140. For example, the ingress module 144 can reorganize the codewords of the stream of codewords from the error correction inserter 132 to transform the codewords from a format where there is one symbol (e.g., one or more bits) per interleaver row to 512 bits per interleaver row, and these 512 bits are written to a write interface of the delay memory 140 (e.g., SDRAM). In the example illustrated, the error correction inserter 132 of the first transceiver 104 provides a first stream of codewords to the interleaver 136 of the first transceiver 104 and the error correction inserter 132 of the second transceiver 108 provides a second stream of codewords to the interleaver 136 of the second transceiver 108.

The egress module 148 reorders data words received from a read interface (e.g., an output interface) of the delay memory 140 at an interleaver size and rate that satisfies a read threshold of the interleaver 136. The read threshold of the interleaver 136 defines a portion (e.g., about 50% or more) of the predetermined size and rate of the delay memory 140 and outputs an interleaved data stream. Stated differently, the egress module 148 receives the data words from the delay memory 140 at the interleaver size and rate and reorganizes the data words into an output stream to achieve the efficient data transfer speeds. In one example, the egress module 148 reorganizes data bits from 512 bits per interleaver row provided at the read interface of the delay memory 140 to one symbol per interleaver row at the egress module 148 output to provide the interleaved data stream. In the example illustrated, the egress module 148 of the first transceiver 104 provides a first interleaved data stream and the egress module 148 of the second transceiver 108 provides a second interleaved data stream.

For the first transceiver 104, the first interleaved data stream is provided to the transmitter 116 and transmitted over the free space link 112 to the receiver 120 of the second transceiver 108. Conversely, for the second transceiver 108, the second interleaved data stream is provided to the transmitter 124 and transmitted over the free space link 112 to the receiver 128 of the first transceiver 104.

Similar to the interleaver 136, the deinterleaver 138 is formed with IC (integrated circuit) chips. Moreover, the interleaver 136 includes a delay memory 152, such as SDRAM. The delay memory 152 has the same properties as the delay memory 140 of the interleaver 136 in some examples. Thus, the delay memory 152 has a storage of, for example, 8 GB (equivalent to 64 Gb or about 6.87×10¹⁰ bits) of storage. Additionally, it is presumed that the delay memory 152 has a minimum efficient data burst size and a minimum efficient read or write block size similar to the delay memory 140 of the interleaver 136. The minimum efficient read or write block size can often be configured in the controller 142 according to the specific needs of the system.

In some examples of the delay memory 152, the minimum efficient data burst size is 512 bits per data word (for example, an SDRAM with an interface width of 64 bits and a burst length of 8), and a minimum efficient read or write block size of 4, such that a total transfer size of 2048 bits (S symbols) are written to or read from the delay memory 140 at a time to ensure efficient data transfer. In other examples, there could be more or less bits in the minimum efficient data burst size and/or the minimum efficient read or write block size.

To ensure that the delay memory 152 reads and writes data in the predetermined size and rate (or some portion thereof) that ensure efficient data transfer speeds, deinterleaver 138 of the first transceiver 104 and the second transceiver 108 include an ingress module 156 and an egress module 160. The ingress module 156 and the egress module 160 of the deinterleaver 138 are configured in the same or similar manner as the ingress module 144 and the egress module 148 of the interleaver 136. The ingress module 156 receives an interleaved data stream and reorganizes the interleaved data stream into a format that is written to the delay memory 152 to achieve the efficient data transfer speeds. Stated differently, the ingress module 156 reorders an input data stream, namely, the interleaved data stream, to provide data words to the write interface of the delay memory 152 at a deinterleaver size and rate that satisfies a write threshold of the deinterleaver 138. The write threshold of the deinterleaver 138 defines a portion (e.g., about 50% or more) of the predetermined size and rate of the delay memory 152 of the deinterleaver. For example, the ingress module 156 of the first transceiver 104 can reorganize the second interleaved data stream from the receiver 128 to transform the first interleaved data stream from a format where there is one symbol (e.g., one or more bits) per interleaver row to 2048 bits (S symbols) per interleaver row, and these 2048 bits are written to a write interface of the delay memory 152 (e.g., SDRAM). Similarly, the ingress module 156 of the second transceiver 108 can reorganize the first interleaved data stream from the receiver 120 to transform the first interleaved data stream from a format where there is one symbol (e.g., one or more bits) per interleaver row to 2048 bits (S symbols) per interleaver row, and these 2048 bits are written to a write interface of the delay memory 152 (e.g., SDRAM).

The egress module 160 reorders data words received from the read interface of the delay memory 152 at a deinterleaver rate size and rate that satisfies a read threshold of the deinterleaver 138. The read threshold of the deinterleaver 138 defines a portion (e.g., about 50% or more) of the predetermined size and rate of the delay memory 152 and outputs a deinterleaved data stream. Stated differently, the egress module 160 receives the data words from the delay memory 152 at the deinterleaver size and rate and reorganizes the data words into a deinterleaved data stream to achieve the efficient data transfer speeds. In one example, the egress module 160 reorganizes data bits from 2048 bits (S symbols) per deinterleaver row provided at the read interface of the delay memory 152 to one symbol per deinterleaver row at the read interface to provide the deinterleaved data stream. In the example illustrated, the egress module 160 of the first transceiver 104 provides a first deinterleaved data stream and the egress module 160 of the second transceiver 108 provides a second deinterleaved data stream.

Stated differently, the interleaver 136 and deinterleaver 138 includes an ingress module 144 or the ingress module 156 which reorders the symbol stream from one symbol per interleaver row at a respective input to S symbols per interleaver row at its output. The interleaver 136 and deinterleaver 138 also include the delay memory 140 or the delay memory 152 which has S symbols per interleaver row at a respective input and output. The interleaver 136 and deinterleaver 138 include the egress module 148 or the egress module 160 which reorders the symbol stream from S symbol per interleaver row at a respective input to one symbol per interleaver row at its output. In these examples, S is the number of symbols to produce an efficient implementation of the delay memory 140 or the delay memory 152. It is noted that for a block interleaver or deinterleaver, the word “row” is be replaced with the word “column” at the appropriate interfaces (block interleaver egress and block deinterleaver ingress).

In general, the operations described in this description include a reordering of symbols that is achieved by receiving a stream of symbols each symbol associated with a different interleaver row and grouping sets of Q symbols each symbol associated with a different interleaver row (ingress symbol buffer). Next, R sets of Q symbols are reordered into Q sets of R symbols, wherein for each set of R symbols each symbol is associated with a same interleaver row (ingress reorder symbols). Next S/R sets of R symbols are reordered into a set of S symbols each symbol associated with a same interleaver row (ingress word buffer). Next, the sets of S symbols are reordered to achieve the desired interleaver or deinterleaver function (delay memory). Next, each set of S symbols is partitioned into S/R sets of R symbols wherein each symbol is from a same interleaver row (egress word buffer). Next, Q sets of R symbols are reordered into R sets of Q symbols wherein each of the Q symbols is from a different interleaver row (egress reorder symbols). Finally, each set of Q symbols is output as a stream of symbols each symbol from a different interleaver row (egress symbol buffer). Each of the parameters Q, R and S are selectable to achieve efficient implementation using the available technologies, such as FPGA, ASIC and memory IC. Input serial to parallel and output parallel to serial functions are used in some examples to implement efficient symbol stream interfaces.

More specifically, for the first transceiver 104, the first deinterleaved data stream is provided to the error corrector 139 of the first transceiver 104. For the second transceiver 108, the second interleaved data stream is provided to the error corrector 139 of the second transceiver 108. The error corrector 139 detects and corrects errors in a received deinterleaved data stream and provides output data (labeled “OUTPUT DATA” in FIG. 1) to an external system. Thus, the error corrector 139 of the first transceiver 104 detects and corrects errors in the first deinterleaved data stream to provide the output data for the first transceiver 104 that matches the input data received at the second transceiver 108. Similarly, the error corrector 139 of the second transceiver 108 detects and corrects errors in the second deinterleaved data stream to provide output data that matches the input data received at the first transceiver 104.

By implementing the communication system 100 of FIG. 1, data transmitted across the free space link 112 is reordered with the interleaver 136 to ensure that data loss due to channel fades of the free space link 112 is distributed across multiple non-contiguous (e.g. non-sequential) data blocks. This curtails the impact of such channel fades and increases the chances that the error corrector 139 can detect and correct errors of a deinterleaved data stream. Furthermore, the interleaver 136 and deinterleaver 138 of the first transceiver 104 and the second transceiver 108 are designed/configured to provide a high data throughput rate for the delay memory 140 and the delay memory 152. Thus, the design of the interleaver 136 and the deinterleaver 138 enables the efficient use of the memory module, for example an SDRAM with GB of storage, by using a relatively large data transfer word size. The examples provided in this description are related to the employment of SDRAM as the memory type used to implement the delay memory 140 and the delay memory 152. However, in various examples, other types of memory are employable. For instance, in an alternative example, High Bandwidth Memory (HBM) that packages multiple SDRAM memory types in a single module (or component) are employed. Moreover, as the capacity of memory increases, new types of memory with large data transfer word sizes may be developed. The procedures described herein is applicable to these emerging memory technologies.

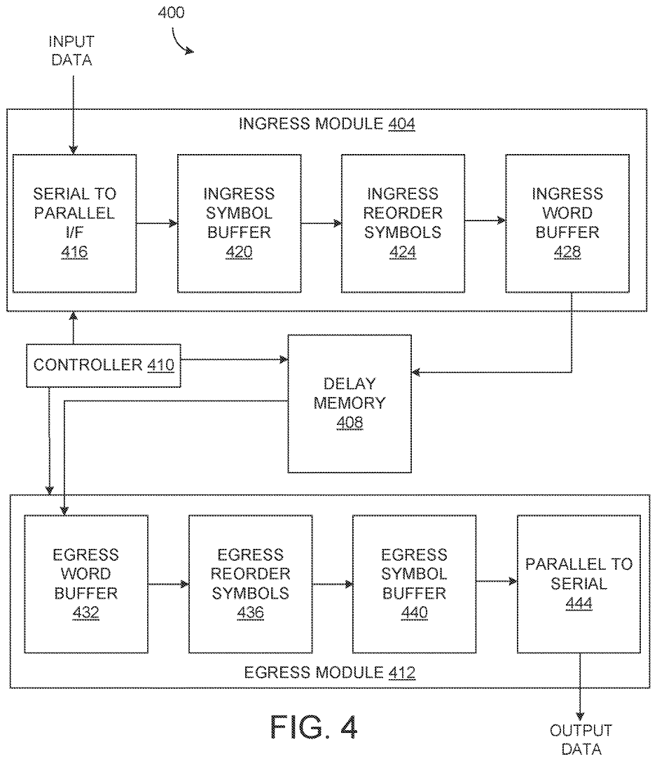

FIG. 4 illustrates a block diagram of a data rearranger 400 that is employable to implement an interleaver or a deinterleaver, such as the interleaver 136 or the deinterleaver 138 of FIG. 1. In such situations, the interleaver or deinterleaver formed with the data rearranger 400 can be implemented as a convolutional interleaver, such as in the first example. Additionally, in other instances, the interleaver or deinterleaver formed with the data rearranger 400 can be implemented as a block interleaver, such as in the second example.

The data rearranger 400 has been assigned a design parameter defining a number of interleaving rows of N. In examples where the data rearranger 400 is implemented as a convolutional interleaver or a convolutional deinterleaver (e.g., the first example), the data rearranger 400 is also assigned a delay factor, B. In examples where the data rearranger 400 is implemented as a block interleaver or block deinterleaver (e.g., the second example), the data rearranger 400 is also assigned a number of interleaver columns, M.

The data rearranger 400 includes an ingress module 404, a delay memory 408 and an egress module 412 coupled in series. The ingress module 404 receives input data (labeled “INPUT DATA” in FIG. 4). In examples where the data rearranger 400 is implemented as an interleaver, the input data is a stream of codewords. The ingress module 404 is implemented with hardware in some examples. More particularly, the ingress module 404 can be implemented on an IC chip, such as an ASIC (application specific integrated circuit) or an FPGA (field programmable gate array).

Operations of the data rearranger 400, including operations of the ingress module 404, the delay memory 408 and the egress module 412 can be controlled by a controller 410. The controller 410 can represent hardware, software or a combination thereof (e.g., hard-wired instructions). Moreover, although FIG. 4 illustrates a single controller, the controller 410 can represent multiple instances of controllers that operate in concert to facilitate the operations of the data rearranger 400, such that the controller 410 can implement a memory controller. The controller 410 can, among other things control clocks used to adjust the timing of operations of the data rearranger 400.

The delay memory 408 has a write interface (e.g., an input interface) and a read interface (e.g., an output interface) that are tuned to transfer (e.g., receive and provide) data words at a predetermined size and rate. The ingress module 404 reorders the input data to provide data words to a write interface (e.g., an input interface) of the delay memory 408 at an interleaver or deinterleaver size and rate that satisfies a write threshold of an interleaver of deinterleaver that implements the data rearranger 400. The write threshold of the interleaver or deinterleaver defines a portion (e.g., 50% or more) of the predetermined size and rate for the delay memory 408. The ingress module 404 includes sub-modules to execute particular operations. In particular, the ingress module 404 includes a serial to parallel interface 416. The serial to parallel interface 416 converts a one symbol input to an ingress length Q symbols output, wherein Q is an integer greater than or equal to one. Q is a selectable design parameter for efficient implementation of the submodules of the data rearranger 400. N may be divisible by Q or N may not be divisible by Q. If the required number of rows N is not divisible by Q, operations of the various modules are adjusted, such as select a value greater than N which is divisible by Q, which can be referred to as N′, then omit operation and/or insert and delete null symbols for the added rows from N to N′−1. For purposes of simplicity of explanation, in the examples provided, it is assumed that N is divisible by Q. More generally, the serial to parallel interface 416 deserializes symbols in the input data to provide an ingress stream of symbols having a first length through parallel paths (e.g., Q number of parallel paths). For example, the parallel interface 416 could be configured to convert a 4 lane signal, such as used for some Ethernet interfaces, of serial one-bit symbol data into a 64-bit wide word formed of 64 one-bit symbols. Thus, in such a situation, Q would be equal to 64, where there would be a one-bit symbol input to the parallel interface 416, and length Q symbols output by the serial to parallel interface 416. Accordingly, the serial to parallel interface 416 provides a stream of parallel symbols (e.g., length Q symbols) along Q number of parallel paths (e.g., 64 paths), such that one symbol is provided per path, which can be referred to as an ingress length Q symbols stream.

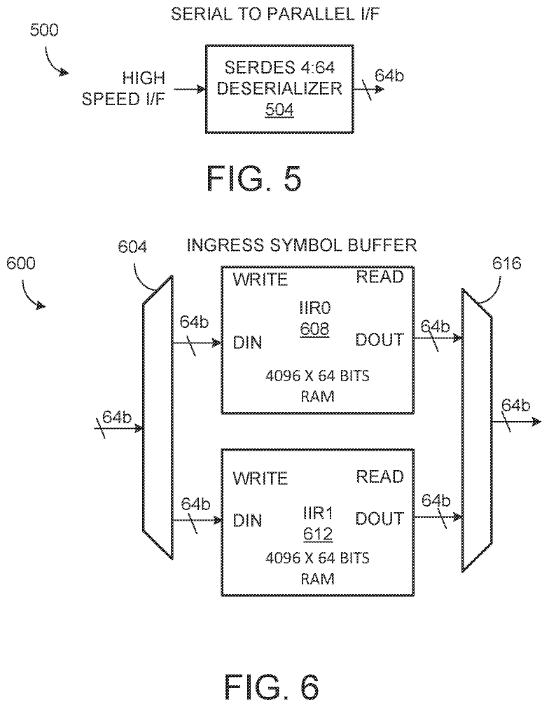

FIG. 5 illustrates an example of a serial to parallel interface 500 that is employable to implement the parallel interface 416 of FIG. 4. The serial to parallel interface 500 includes a 4:64 SERDES (serial/deserializer) deseralizer 504 that converts a serial signal provided at a 4-lane high speed interface (labeled in FIG. 5 as HIGH SPEED I/F) into a 64-bit parallel signal. For example, the serial signal could be a 1 bit per symbol signal that is provided at a bursty data rate of 32 Gbps (gigabits per second).

Referring back to FIG. 4, the ingress length Q symbols stream (e.g., 64 one-bit symbols) is received at an ingress symbol buffer 420. The ingress symbol buffer writes length Q symbols NR/Q number of times (NR symbols) and then repeats. R is a selectable design parameter for efficient implementation of the submodules of the data rearranger 400. The ingress symbol buffer 420 outputs an ingress buffered length Q symbols stream that is provided along Q paths. More generally, the ingress symbol buffer 420 buffers the ingress stream of length Q symbols to output a buffered ingress stream of length Q symbols.

The ingress symbol buffer 420 has a ping-pong memory structure of input RAM modules that enables buffering of the length Q symbols in the ingress length Q symbols stream with an unknown burstiness. More particularly, in the ping-pong configuration a first input RAM module stores a first set of length Q symbols of the ingress stream of length Q symbols contemporaneously with a second input RAM module outputting a second set of length Q symbols of the ingress stream of length Q symbols for the buffered ingress stream of length Q symbols. In examples where the ingress length Q symbols stream data rate variation is limited or controlled by an input buffer (e.g., a first in first out (FIFO) buffer), the ping-pong memory structure can be avoided.

FIG. 6 illustrates an example of an ingress symbol buffer 600 that is employable to implement the ingress symbol buffer 420 of FIG. 4. The ingress symbol buffer 600 includes a demultiplexer 604 (alternatively referred to as a one-to-two switch) that receives a 64-bit parallel signal (e.g., length Q symbols) at an input port. A selection signal (not shown) from a controller (e.g., the controller 410 of FIG. 4) alternates between writing to a first ingress input RAM module 608 (labeled “IIR0” in FIG. 6) and a second ingress input RAM module 612 (labeled IIR1 in FIG. 6). In the example illustrated, the first ingress input RAM module 608 and the second ingress input RAM module 612 are RAM modules that hold up to 4096 64-bit words (e.g., 4096×64 bit RAM), but in other modules, other sizes are employable. The ingress symbol buffer 600 is configured in a ping-pong arrangement, such that 64 bits (e.g., a block of Q symbols) provided to the demultiplexer 604 are written to the first ingress input RAM module 608, this is repeated until NR/Q consecutive blocks of Q symbols (NR symbols) are written to the first ingress input RAM module 608. The selection signal then controls demultiplexer 604 to direct the next NR/Q consecutive blocks of Q symbols (NR symbols) to be written to the second ingress input RAM module 612. The selection signal cause subsequent sets of NR symbols to be written to each ingress input RAM in alternating fashion.

The first ingress input RAM module 608 and the second ingress input RAM module 612 write the 64 symbols (1 bit per symbol) to a multiplexer 616 (alternatively referred to as a two-to-one switch) that has a selection signal (not shown) from a controller (e.g., the controller 410 of FIG. 4) to alternate reading NR symbols from the first ingress input RAM module 608 and NR symbols from the second ingress input RAM module 612. The output symbol sequence from the ingress input RAM is different than the input symbol sequence to the ingress input RAM, such that subsequent sets of symbols corresponding to the first Q interleaver rows (rows 0 to Q−1) are output in series R times (QR symbols) before moving to the next set of interleaver rows (rows Q to 2Q−1) to be output in series R times (QR symbols), continuing this pattern N/Q times until NR symbols from the input RAM module have been output. As an example, the sequence of the Q symbol stream input to the ingress input RAM module are written to Q symbols wide memory locations in the sequence 0, 1, 2, up to NR/Q−1 (NR symbols) and the sequence of the Q symbol stream output from the ingress input RAM module are read from memory locations in steps of size N/Q, in the sequence 0, N/Q, 2N/Q, up to (R−1)N/Q, then 1, N/Q+1, 2N/Q+1, up to (R−1) N/Q+1, then 2, N/Q+2, 2N/Q+2, up to (R−1)N/Q+2, repeating this progression until all of the NQ symbols have been output from final addresses N/Q−1, 2N/Q−1, 3N/Q−1, up to RN/Q−1. In this example N is divisible by Q, however the general case of N not divisible by Q may be implemented with modifications.

In an alternative design, the ingress symbol buffer 600 can be implemented with a single ingress input RAM module, wherein write and read addresses are swapped for each pass of data transfer through the RAM module, which is for each set of NR symbols. In this manner, the read order is sequential and the write order is stepped for one read and write pass through the ingress symbol buffer 600, and the read order and the write order are swapped for the next pass.

Referring back to FIG. 4, the ingress symbol buffer provides each Q symbols stream to an ingress reorder symbols submodule 424. The ingress reorder symbols submodule 424 has Q shift registers of length R symbols. For simplification, the explanations provided presume that Q and R are equal in size. The ingress reorder symbols submodule is configured for the ingress input RAM module read address sequence described previously. The shift registers will be loaded with a sequence of symbols for a set of interleaving rows, namely, rows k to k+Q−1, repeated R number of times to fill shift registers (1 symbol to each shift register, repeated R times, for a total of R symbols per shift register) of the ingress reorder symbols submodule 424. This loading occurs in an iterative operation for values of k, specifically, k=0, Q, 2Q and up to N−Q. At the end of each iteration there are R symbols in each shift register, those symbols are output from the ingress reorder symbols submodule 424 in sequence from the first to last shift register, such that each output block of R symbols correspond to a single interleaver row. In this manner, the ingress reorder symbols submodule 424 writes the reordered length R symbols from each of the Q shift registers to the ingress word buffer 428.

More generally, the ingress reorder symbols submodule 424 stores the symbols of the ingress stream of symbols of length Q output by the ingress symbol buffer 420 in shift registers. There are Q number of shift registers, and the ingress reorder symbols submodule 424 is configured such that one symbol of the ingress stream of length Q symbols is stored in each of the Q shift registers, and the shift registers output a reordered stream of symbols having length R symbols.

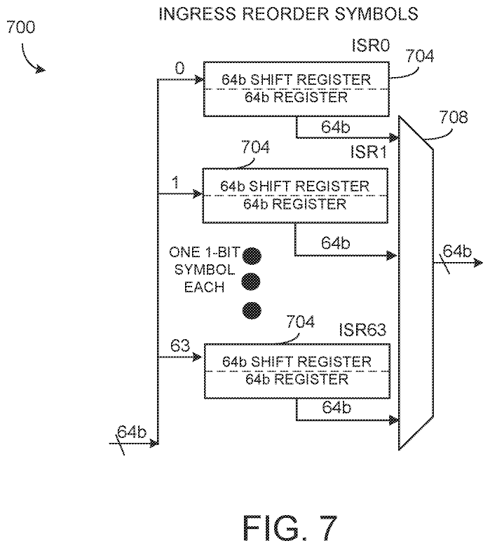

FIG. 7 illustrates an ingress reorder symbols submodule 700 that is employable to implement the ingress reorder symbols submodule 424 of FIG. 4. The reorder symbols submodule 700 includes 64 ingress shift registers 704, labeled ISR0 . . . ISR63. More generally, the reorder symbols submodule 700 includes Q number of ingress shift registers 704.

The ingress shift registers 704 are arranged to receive an ingress stream of 64 one-bit symbols (e.g., an ingress stream of length Q symbols, more generally) from an ingress symbol buffer, such as the ingress symbol buffer 600 of FIG. 6 and/or the ingress symbol buffer 420 of FIG. 4. For each such 64 one-bit symbols, one symbol is written to the each of the 64 ingress shift registers 704. For instance, for a given 64-bits from the ingress symbol buffer, a first bit (bit 0) is written to the first ingress shift register 704 (ISR0), a second bit (bit 1) is written to the second shift register 704 (ISR1) . . . and a 64th bit is written to the 64th ingress shift registers 704 (ISR63).

The ingress shift registers 704 are configured to store (queue) 64-bits (e.g., a reordered ingress stream of length R symbols, more generally). Responsive to reaching the 64-bits, the 64-bits are shifted to a register of the ingress shift registers 704. Responsive to shifting the 64-bits to the register, the ingress shift registers 704 can store a next 64-bits in the ingress shift register 704.

The 64 ingress shift registers 704 (ISR0 . . . ISR63) output the value stored in the corresponding register to a multiplexer 708. A selection signal (not shown) from a controller (e.g., the controller 410 of FIG. 4) causes the ingress shift registers 704 to select a particular ingress shift register 704, and the output of the selected ingress shift register 704 is output by the multiplexer 708. The selection signal causes the multiplexer 708 to cycle through the 64 ingress shift registers 704, such that the multiplexer 708 outputs symbols that have a 64-bit length (length R symbols, more generally). Moreover, because the ingress shift registers 704 each receive a single bit of each 64-bit input (length Q symbols, more generally), the order of the 64 one-bit symbols (R symbols) output by the multiplexer 708 is different than the 64 one-bit symbols (Q symbols) in the ingress stream of 64 one-bit symbols provided to the ingress shift registers 704. The multiplexer 708 outputs a reordered ingress stream of 64 one-bit symbols (e.g., a reordered ingress stream of length R symbols, more generally).

Referring back to FIG. 4, as noted, the ingress reorder symbols submodule 424 outputs an ingress stream of length R symbols. This ingress stream of length R symbols is provided to an ingress word buffer 428. The ingress word buffer 428 is configured to write the length R symbols of the ingress stream of length R symbols for each Row k in sequence k=0 to N−1 (NR symbols), and repeat the sequence (S/R) times to store a total of NS symbols. The ingress word buffer 428 is configured to read the length R symbols of the ingress stream of length R symbols for Row k (S/R) times to form data words of length S symbols for Row k, stepping through values of k=0 to N−1. The ingress word buffer 428 outputs an ingress stream of data words of length S symbols.

More generally, the ingress word buffer 428 receives the ingress stream of length R symbols from the shift registers of the ingress reorder symbols submodule 424 in a sequential order. The ingress word buffer 428 concatenates multiple symbols of the ingress stream of symbols of length R to provide the ingress stream of data words of length S symbols to the write interface of the delay memory 408.

In some examples, the ingress word buffer 428 includes output RAM modules arranged in a ping-pong configuration. In such examples, a first set of the output RAM modules stores a first set of the length R symbols contemporaneously with a second set of the output RAM module outputting a second set of symbols of the ingress stream of length R symbols for concatenation to provide the ingress stream of data words of length S symbols. In other examples, the ping-pong arrangement is avoided by controlling timing of writes from the ingress reorder symbols submodule 424 to the ingress word buffer 428.

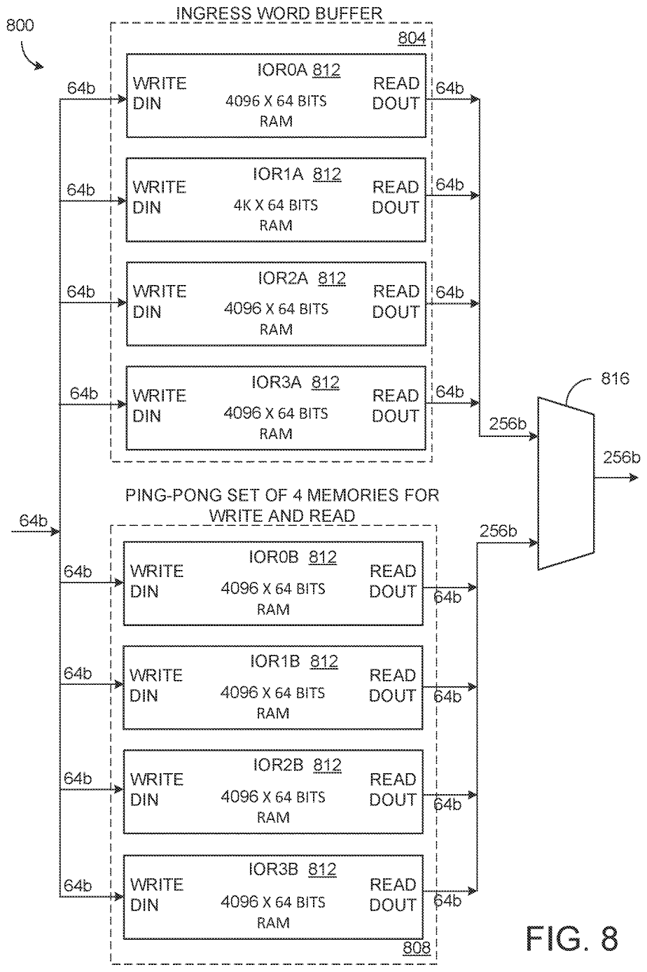

FIG. 8 illustrates an example of an ingress word buffer 800 that is employable to implement the ingress word buffer 428 of FIG. 4. The ingress word buffer receives an ingress stream of 64 one-bit symbols, such as the ingress stream of length R symbols provided from the ingress reorder symbols submodule 424 of FIG. 4 and/or the reorder symbols submodule 700 of FIG. 7.

The 64 one-bit symbols are provided to a first set of ingress output RAMs 804 or a second set of ingress output RAMs 808. The first set of ingress output RAMs 804 and the second set of ingress output RAMs 808 are formed of ingress output RAMs 812. The ingress output RAMs 812 of the first set of ingress output RAMs 804 (e.g., group A) are labeled IOR0A . . . IOR3A and the second set of ingress output RAMs 808 (e.g., group B) are labeled IOR0B . . . IOR3B. In the example illustrated, there are 4 ingress output RAMs 812 in the first set of ingress output RAMs 804 and the 4 ingress output RAMs 812 in the second set of ingress output RAMs 808. However, in other examples there are more or less ingress output RAMs 812 in the first set of ingress output RAMs 804 and the second set of ingress output RAMs 808. To generalize the explanation, let T denote the number of ingress output RAMs 812 in a set of ingress output RAMs 804 or 808, where T is an integer greater than or equal to one.

In the example illustrated, the ingress output RAMs 812 are RAM modules that hold 4096 64-bit words (e.g., 4096×64 bit RAM), but in other modules, other sizes are employable. The examples provided support situations where (i) N is 2048 and S is 512 one-bit symbols, (ii) N is 1024 and S is 1024 one-bit symbols and (iii) N is 512, and S is 2048 one-bit symbols. In fact, for 4 RAMs at 4096×64 bits (1048576 bits), any choice of N and S is employable where NS symbols (accounting for the number of bits per symbol) is less than or equal to this number of bits. The ingress word buffer 800 is configured in a ping-pong arrangement, such that streams of 64 one-bit symbols (R symbols) are provided to the first set of ingress output RAMs 804 repeatedly, NS/R times, until a block of NS symbols have been provided. The ingress word buffer 800 then ping-pongs, such that the next block of NS symbols is provided to the second set of ingress output RAMs 808, continuing in alternating fashion. For example, a first N consecutive 64-bit words (R symbols) are written to IOR0A (NR symbols), a next N consecutive 64-bit words are written to IOR1A, a next N consecutive 64-bit words are written to IOR2A, and a next N consecutive 64-bit words are written to IOR3A (the T equal to 4 ingress output RAMs 812), such that NTR symbols have been written to the first set of ingress output RAMs 804. This is repeated S/TR times until a block of NS symbols have been written to the first set of ingress output RAMs 804. Subsequently, ingress word buffer 800 ping-pongs and a first N consecutive 64-bit words (R symbols) are written to IOR0B, a next N consecutive 64-bit words are written to IOR1B, a next N consecutive 64-bit words are written to IOR2B, and a next N consecutive 64-bit words are written to IOR3B (the T equal to 4 ingress output RAMs 812), such that NTR symbols have been written to of the second set of ingress output RAMs 808. This is repeated S/TR times until a block of NS symbols have been written to the seconds set of ingress output RAMs 808. Stated differently, each 64 one-bit symbol stream (R symbols) input to the ingress word buffer 800 is written to a given ingress output RAM 812. To execute this, in some situations, for each incoming 64 one-bit symbols, only one ingress output RAMs 812, a selected ingress output RAMs 812 is set to a write operation (remaining ingress output RAMs 812 are set to read-only operation). The selected ingress output RAMs 812 stores the 64 one-bit symbols in RAM.

The ingress output RAMs 812 store buffered 64-bit words (R symbols) in the manner explained. Additionally, each of the T ingress output RAMs 812 of the first set of ingress output RAMs 804 contemporaneously output to the multiplexer 816 the stored 64-bit words (R symbols from each, for a total of RT symbols) which correspond to a single interleaver row and which have been stored the longest and not previously output. In this example, the T equal to 4 outputted 64-bit words are concatenated to form a 256-bit word that is output for a delay memory (e.g., the delay memory 408 of FIG. 4). In other examples, a different number of bits per ingress output RAM 812 and/or different quantities of ingress output RAMs 812 can be used to concatenate to more or less than 256-bit words to output to the delay memory 408 of FIG. 4. The output from the ingress output RAMs 812 repeat in sequence of interleaver rows from 0 to N−1 (RT symbols for each interleaver row, for a total of NRT symbols), then repeat for the interleaver rows S/RT times (each iteration outputting the next longest stored symbols) until NS symbols from the first set of ingress output RAMs 804 are output to the multiplexer 816. Contemporaneously, in a ping-pong operation, 64-bit words (R symbols) are written to ingress output RAMs 812 of the second set of ingress output RAMs 808. This repeats until NS symbols are written to the second set of ingress output RAMs 808. Subsequently, in a ping-pong operation, the ingress output RAMs 812 of the second set of ingress output RAMs 808 output stored 64 one-bit symbols to a multiplexer 816 in the same order as previously described for the first set of ingress output RAMs 804. The T equal to 4 outputted 64-bit words are concatenated to form a 256-bit word that is output to a delay memory 408 of FIG. 4. The output from the ingress output RAMs 812 continues until NS symbols from the second set of ingress output RAMs 808 are output to the multiplexer 816.

In an alternative design, the ping-pong arrangement is avoided by controlling timing of writes from the ingress reorder symbols submodule to the ingress word buffer 800. In this case, instead of a ping-pong example of writing R symbols N times to a given ingress output RAM 812 (NR symbols) before proceeding to the next ingress output RAM 812, in a non-ping-pong example write R symbols to each ingress output RAM 812 in the sequence {1^{st}, 2^{nd}, 3^{rd}, . . . , T^{th}} (RT symbols), repeat writing R symbols S/R times (S symbols, with S/T symbols to each ingress output RAM 812), next circular shift by one position the write order to the T ingress output RAMs 812, then write R symbols to each ingress output RAM 812 in the sequence {2^{nd}, 3^{rd}, . . . , T^{th}, 1^{st}}, repeat writing R symbols S/R times (S symbols, with S/T symbols to each ingress output RAM 812), continue these operations until the circular shift by one position results in the sequence {T^{th}, 1^{st}, 2^{nd}, . . . , T−1^{th}}, repeat writing R symbols S/R times (S symbols, with S/T symbols to each ingress output RAM 812). At this point, a total of ST symbols have been written to the set of ingress output RAMs 804. The sequence of operations repeats a total of N/T times until a total of NS symbols have been written to the set of ingress output RAMs 804. The process repeats for the next NS symbols. The output read sequence is such that each of the T ingress output RAMs 812 of the set of ingress output RAMs 804 contemporaneously output to the multiplexer 816 the stored 64-bit words (R symbols from each, for a total of RT symbols) which correspond to a single interleaver row and which have been stored the longest and not previously output. The output from the ingress output RAMs 812 repeat in sequence of interleaver rows from 0 to N−1 (RT symbols for each interleaver row, for a total of NRT symbols), then repeat for interleaver rows S/RT times (each iteration outputting the next longest stored symbols) until NS symbols from the set of ingress output RAMs 804 are output to the multiplexer 816. This output sequence is the same as in the ping-pong example with the addition of a corresponding circular shift in the concatenation function of the multiplexer 816 after every S symbols (every S/RT reads of R symbols from T ingress output RAMs 812) repeating N times for a total of NS symbols, then repeats. Each pass of NS symbols through the set of ingress output RAMs 804, the write locations follow the same sequence subsequent to the locations being read in the last S/RT accesses (the locations of the previous S symbols output). Each pass through the set of ingress output RAMs 804, the read location sequence alternates between two patterns which implement the described output sequence.

Whether or not a ping-pong arrangement is employed, the example ingress word buffer 800 outputs an ingress stream of 256-bit data words. In some examples, multiple data words which correspond to the same interleaver row (S symbols) are written to the write interface of the delay memory in a data burst operation to increase a throughput. For instance, in some examples, 8 of the 256-bit words (corresponding to a single interleaver row) are written to the write interface of the delay memory to ensure that each write operation to the delay memory write interface has 2048 bits comprising S symbols (e.g., a delay memory with a 64-bit wide interface using a burst length of 8 and block size of 4).

Referring back to FIG. 4, as noted, the ingress word buffer 428 provides an ingress stream of data words in a format rapidly consumable by the delay memory 408. More particularly, the delay memory 408 (e.g., SDRAM) includes the write interface configured to receive data words at the interleaver or deinterleaver size and rate. As illustrated in FIG. 6, this size can be, for example, 2048 bits of bursty data formed with 8 256-bit words.

In examples where the data rearranger 400 can be a convolutional interleaver, a convolutional deinterleaver, a block interleaver or a block deinterleaver in various examples. In each such situation, operations of the ingress module 404 and the egress module 412 remain the same, and the control of the delay memory 408 is adjusted. Thus, in instances of the first example, the data rearranger 400 is implemented with a convolutional interleaver or a convolutional deinterleaver. Additionally, in instances of the second example, the data rearranger 400 is implemented with a block interleaver or a block deinterleaver.

In examples where the data rearranger 400 is implemented as a convolutional interleaver (e.g., in the first example), the delay memory 408 writes S symbols data words for row k to allocated memory of the delay memory 408 for that row. This process is executed for value of k=0 to N−1. Similarly, the delay memory 408 reads S symbols data words for row k from the allocated memory of the delay memory 408 for that row. This process is executed for values of k=0 to N−1 to provide an egress stream of data words (e.g., output stream of data words) in the first example. These operations are repeated for delay factor B memory segments for rows N.

In examples where the data rearranger 400 is implemented as a block interleaver (e.g., in the second example), the delay memory 408 writes length S symbols data words for row k to the allocated memory of the delay memory 408 for that row. This process is executed for each of the M columns of the block interleaver for values of k=0 to N−1 (N rows). Similarly, the delay memory 408 reads length S symbols data words for column k from the allocated memory of the delay memory 408 for that column. This process is executed for each of the N rows of the block interleaver for values of k=0 to M−1 (M columns), to provide an egress stream of data words (e.g., a stream of output data words) in the second example.

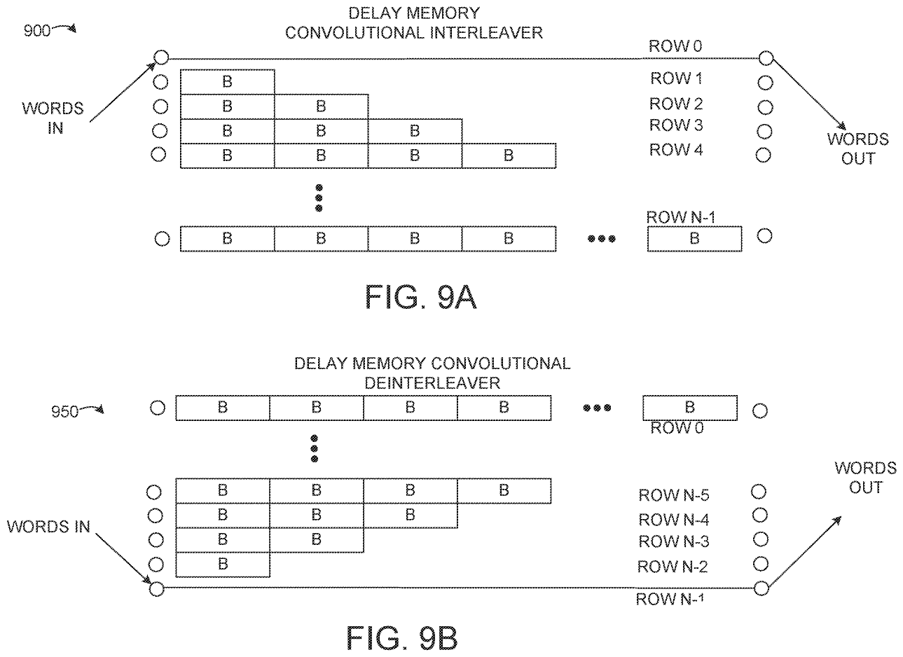

FIG. 9A illustrates a delay memory convolutional interleaver 900. The delay memory convolutional interleaver represents operations of the delay memory 408 of FIG. 4 during examples where the data rearranger 400 implements a convolutional interleaver, such as an instance of the first example. The delay memory convolutional interleaver 900 operates in a similar manner as the convolutional interleaver 200 described with respect to FIG. 2A. Operations of the delay memory convolutional interleaver 900 are controlled by a controller, such as the controller 410 of FIG. 4.

The delay memory convolutional interleaver 900 has an ingress stream of data words (labeled “WORDS IN” in FIG. 9A) that represent a stream of data words provided to the write interface of the delay memory (e.g., delay memory 408 of FIG. 4). The ingress stream data words can be provided by an ingress word buffer, such as the ingress word buffer 428 of FIG. 4. Similarly, the delay memory convolutional interleaver 900 provides an egress stream of data words (labeled “WORDS OUT” in FIG. 9A) that represent a stream of data words provided at a read interface (e.g., an output interface) of the delay memory.

In general, the delay memory convolutional interleaver 900 stores the data words of the ingress stream of data words received at the write interface as a block of data in the delay memory. The block of data has a set number of rows (N row), and the data words received at the write interface of the delay memory are rearranged in a predefined and reversible pattern. Accordingly, the data words of the egress stream of data words provide at the read interface of the delay memory have a different order than the data words of the ingress stream of data words received at the write interface of the delay memory. The delay memory convolutional interleaver 900 is configured such that rows of a block of data in the delay memory have increasing lengths (e.g., length 0 for row 0, length B symbols for row 1, length 2B for row 2 . . . length (N−1) B for row N−1). Moreover, the increasing lengths of the rows defines a set delay added between data words consecutively received at the write interface and that are provided at the read interface.

Continuing with the first example, the number of interleaving rows, N is set to 4096 and the delay factor, B is set to 8192 one-bit symbols. Additionally, it is presumed that each incoming data word has a size set to 256 bits, corresponding to S symbols, (e.g., equal to 1/32 of B in this example for simplicity). The delay memory convolutional interleaver 900 can be analogized as a set of shift registers with different lengths, wherein each shift register represents an interleaver row, however, the actual hardware implementation is different. In this analogy, each incoming data word is placed in a different shift register, and these registers delay the data words by different amounts. In an actual hardware implementation, each incoming data word is written to a specific address, and an order of read address provides the delay. Accordingly, data words passing through the delay memory convolutional interleaver 900 are rearranged in a predefined and reversible pattern. Accordingly, the egress data words of the delay memory convolutional interleaver 900 have a different order than the ingress words of the delay memory convolutional interleaver 900.

As noted, the operations of the delay memory convolutional interleaver 900 are similar to the operations of the convolutional interleaver 200 of FIG. 2A, where the incoming symbols of FIG. 2A are replaced with ingress S symbols data words (labeled “WORDS IN” in FIG. 9A), and outgoing symbols of FIG. 2A are replaced with egress S symbols data words (labeled as “WORDS OUT” in FIG. 9A). Thus, as illustrated, for each of the N interleaver rows, a different delay is applied. Specifically, for row 0, there is 0 delay, for row 1 there is a delay of B symbols, and for row N−1 (a last row), there is a delay of (N−1) B symbols. Accordingly, the first incoming data word (word 0) has a delay of 0, and the Nth incoming data word (word N−1) has a delay of (N−1) B symbols). Continuing with the sequence, data word N (the N+1^{th} word) has a delay of 0, and the pattern repeats.

The data words are written to predefined memory addresses for each row of the delay memory convolutional interleaver 900 in an order that provides the delay. As described herein, the delay memory module (the delay memory 408 of FIG. 4) transfers data words of size S symbols, and the delay factor B is defined as a number of symbols. In some examples, B is divisible by S and in other examples, B is not divisible by S. If B is not divisible by S, then the operations of the delay memory may be adjusted, for example at the appropriate instances insert a number of null symbols along with data symbols to form S symbol blocks which result in a total of B data symbols written to the delay memory, and discard the null symbols when read from the delay memory. For simplicity of explanation, the following assumes that B is divisible by S. For row 0, the delay is 0, such that there is only one address assigned to row 0 in some examples. Additionally, for row 1, there would be B/S number of addresses that each hold one data word of size S symbols, and each address represents a slot. For row 2, there would be 2B/S number of addresses, and this sequence would continue until row N−1, which would have (N−1) B/S number of addresses. During a write sequence, sequential data words are written to consecutive rows (where row N−1 and row 0 are considered consecutive rows), and during each write to a given row, a next write to the given row is written to a next address (e.g., next slot). For example, suppose that word 1 was written to the first address in row 1 (presuming that word 0 with 0 delay is written to row 0). On a subsequent cycle (after N number of data words are written to the N number of rows), the next word written to row 1 would be written to the second address in row 1. This process would continue for the N number of rows.

The predefined and reversible pattern used to arrange the egress stream of data words sequentially outputs a data word from each row that has a longest delay of the row. For data words written to row 0, this delay is 0. For every other row, the oldest data word is the word located one memory address higher than the previous address written to for a given row. Thus, continuing with the example where word 1 was written to the first address in row 1, in a read operation of row 1 would provide the word written to the second address in row 1. This process would continue for the N number of rows. Accordingly, the write operations and read operations can be executed contemporaneously. That is, the delay memory convolutional interleaver 900 does not need to be filled with data words before providing the egress stream of data words. At the initial start of use the egress stream of data words may be undefined or random values previously contained in the delay memory, which are ultimately discarded or ignored at the destination convolutional deinterleaver.

FIG. 9B illustrates a delay memory convolutional deinterleaver 950. The delay memory convolutional deinterleaver 950 represents operations of the delay memory 408 of FIG. 4 during examples where the data rearranger 400 implements a convolutional deinterleaver. The delay memory convolutional deinterleaver 950 has an ingress stream of data words (labeled “WORDS IN” in FIG. 9B) that represent an ingress stream of data words provided to a write interface (e.g., an input interface) of the delay memory (e.g., delay memory 408 of FIG. 4). The ingress stream of data words can be provided from an ingress word buffer, such as the ingress word buffer 428 of FIG. 4 and/or the ingress word buffer 800 of FIG. 8. Similarly, the delay memory convolutional deinterleaver 950 provides an egress stream of data words (labeled “WORDS OUT” in FIG. 9A). The egress stream of data words of the delay memory convolutional deinterleaver 950 represent a stream of data words provided at a read interface (e.g., an output interface) of the delay memory. Operations of the delay memory convolutional interleaver 900 are controlled by a controller, such as the controller 410 of FIG. 4.

Continuing with the first example, the number of interleaving rows, N is set to 4096 and the delay factor, B is set to 8192 one-bit symbols. Additionally, in contrast to the delay memory convolutional interleaver 900 of FIG. 9A, in the delay memory convolutional deinterleaver 950 the delay decreases for each row so as to reverse the interleaving of the delay memory convolutional interleaver 900 of FIG. 9A. Thus, the output symbols of the delay memory convolutional interleaver 950 match an order of the input symbols of the delay convolutional interleaver 900 of FIG. 9A. However, to achieve this, the symbols are reordered by the delay memory convolutional deinterleaver 950, such that the input symbols of the delay memory convolutional deinterleaver 950 are in a different sequence than the output symbols of the delay memory convolutional deinterleaver 950.

In particular, operations of the delay memory convolutional deinterleaver 950 are similar to the operations of the convolutional deinterleaver 250 of FIG. 2B, where the incoming symbols of FIG. 2B are replaced with the incoming S symbols data words, and outgoing symbols of FIG. 2B are replaced with the outgoing S symbols data words. Thus, as illustrated, for each of the N deinterleaver rows, a different delay is applied. Specifically, for row 0, there is a delay of (N−1) B symbols, for row 1 there is a delay of (N−2) B symbols, and for row N−1 (a last row), there is a delay of 0. Accordingly, the first incoming data word (word 0) has a delay of (N−1) B symbols, and the Nth incoming data word (word N−1) has a delay of 0. Continuing with the sequence, data word N (the N+1^{th} word) has a delay of (N−1) B symbols, and the pattern repeats.

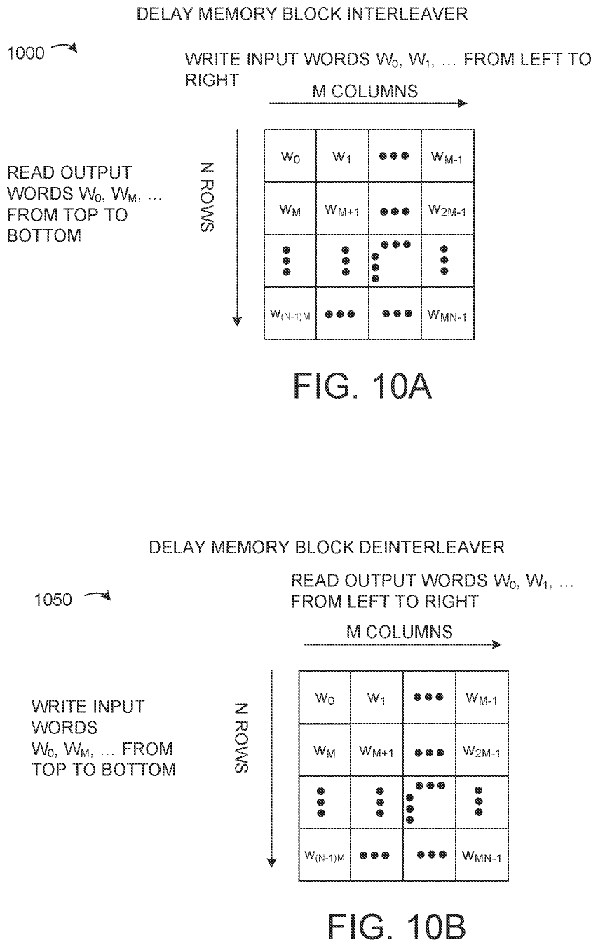

FIG. 10A illustrates a delay memory block interleaver 1000. The delay memory block interleaver represents operations of the delay memory 408 of FIG. 4 during examples where the data rearranger 400 implements a block interleaver, such as an instance of the second example. In some examples, the incoming data words are 256-bit words, but in other examples, larger or smaller data words are also employable. Operations of the delay memory block interleaver 1000 are controlled by a controller, such as the controller 410 of FIG. 4.

The delay memory block interleaver 1000 receives an ingress stream of incoming S symbols data words provided from a word buffer, such as the ingress word buffer 428 of FIG. 4 and/or the ingress word buffer 800 of FIG. 8. The incoming data words are provided at a write interface (e.g., an input interface) of the delay memory. In response to the incoming data words, the delay memory block interleaver 1000 writes the incoming data words in the manner illustrated. In particular, in each row, there are M number of data words written (e.g., data words W₀ . . . W_{M-1} for row 0) for M number of columns. Moreover, this pattern is executed until the delay memory block interleaver 1000 is filled for the N number of rows.

The delay memory block interleaver 1000 also provides an egress stream of outgoing data words. The egress stream of data words are provided at a read interface (e.g., an output interface) of the delay memory. The output symbols are provided as columns. Stated differently, for each of the M number of columns, there are N number of rows. The egress stream of data words are reordered (relative to the ingress stream of data words) such that one data word from each row of a given column is output. For example, for column 0, symbols W₀, W_{M}, W_{2M} . . . W_{(N-1)M} are output in sequence. Similarly, advancing to column 1, data words W₁, W_{M+1}, W_{2M+2} . . . W_{(N-1)M+1} are output next. Thus, the delay memory block interleaver 1000 rearranges the data words passing through to apply a predefined and reversible pattern.

In general, the delay memory block interleaver 1000 stores the data words of the ingress stream of data words received at the write interface as a block of data in the delay memory. The block of data includes a set number of rows (N rows), and the data words received at the write interface of the delay memory are rearranged in a predefined and reversible pattern. Accordingly, the data words of the egress stream of data words provided at the read interface of the delay memory have a different order than the data words of the ingress stream of data words received at the write interface of the delay memory. The delay memory block interleaver 1000 is configured such that rows of the block of data in the delay memory have a same length (length M), and the length of the rows defines a set delay added between data words consecutively received at the write interface and that are provided at the read interface of the delay memory.

FIG. 10B illustrates operations of a delay memory block deinterleaver 1050. The delay memory block deinterleaver 1050 represents operations of the delay memory 408 of FIG. 4 during examples where the data rearranger 400 implements a block deinterleaver, such as an instance of the second example. In some examples, the incoming data words are 256-bit words, but in other examples, larger or smaller data words are also employable. Operations of the delay memory block interleaver 1000 are controlled by a controller, such as the controller 410 of FIG. 4.

The delay memory block deinterleaver 1050 receives an ingress stream of S symbols data words from a word buffer, such as the ingress word buffer 428 of FIG. 4 and/or the ingress word buffer 800 of FIG. 8 and provides an egress stream of data words. Conceptually, the delay memory block deinterleaver 1050 has a same format as the delay memory block interleaver 1000 of FIG. 10A. The incoming data words are provided at a write interface (e.g., an input interface) of the delay memory and the outgoing data words are provided at a read interface (e.g., output interface) of the delay memory.

More particularly, to fill the delay memory block deinterleaver 1050, the incoming data words are written as columns 0 . . . M−1, with each column having N number of symbols stored therein. Accordingly, column 0 stores the incoming data words W₀, W_{M}, W_{2M} . . . W_{(N-1)M} in sequence. Similarly, advancing to column 1, data words W₁, W_{M+1}, W_{2M+2} . . . W_{(N-1)M+1} are stored next. The delay memory block deinterleaver 1050 provides an egress stream of data words that are read as rows of the delay memory block deinterleaver 1050. Specifically, the egress stream of data words has a sequence of W₀, W₁, W₂ . . . W_{M-1} for row 0, and the egress stream of outgoing data words continues to W_{M}, W_{M}+1, W_{M}+2 . . . W_{2M}-1 for row 1. Thus, the stream of outgoing data words of the delay memory block deinterleaver 1050 matches a sequence of the stream of input symbols of the block interleaver 1000 of FIG. 10A. However, to achieve this, the data words are reordered by the delay memory block deinterleaver 1050, such that the incoming data words of the delay memory block deinterleaver 1050 are in a different sequence than the outgoing data words of the delay memory block deinterleaver 1050.

Referring back to FIG. 4, the delay memory 408 provides the egress stream of data words of length S symbols to the egress module 412. The egress module 412 receives the stream of egress stream of data words. The egress module 412 is implemented with hardware in some examples. More particularly, the egress module 412 can be implemented on an IC chip, such as an ASIC (application specific integrated circuit) or an FPGA (field programmable gate array).

The egress module 412 reorders the egress stream of data words of length S symbols received from the read interface of the delay memory 408 at an interleaver or deinterleaver size and rate that satisfies a read threshold for the interleaver or deinterleaver that implements the data rearranger 400 and provides an output data stream. The read threshold for the interleaver or deinterleaver defines a portion (e.g., about 50% or more) of the predetermined size and rate for the delay memory 408. The output data stream can be a stream of serial data, such as a stream of interleaved data or a stream of deinterleaved data. Stated differently, the egress module 412 receives the egress stream of data words from the delay memory 152 at the interleaver or deinterleaver size and rate and reorganizes the data words of the egress stream of data words into an interleaved data stream or a deinterleaved data stream to achieve the efficient data transfer speeds.

The egress module 412 includes submodules to execute particular operations. In particular, the egress module 412 includes an egress word buffer 432. The egress word buffer 432 is configured to partition the egress stream of length S symbols words for Row k into (S/R) sets of length R symbols for Row k, stepping through values of k=0 to N−1. The egress word buffer 432 outputs an egress stream of length R symbols (e.g., 64 one-bit symbols in some examples).

More generally, the egress word buffer 432 receives the egress stream of length S symbols data words from the read interface of the delay memory 408. The egress word buffer 432 separates each length S symbols data word of the egress stream to provide the egress stream of symbols of length R symbols.

In some examples, the egress word buffer includes input RAM modules arranged in a ping-pong configuration. In a ping-pong configuration a first set of the input RAM modules stores a first set of length R symbols (separated from the egress stream of length S symbols data words) contemporaneously with a second set of input RAM modules outputting a second set symbols of the egress stream of length R symbols. In other examples, the ping-pong arrangement is avoided by controlling timing of reads of the length S symbols data words of the egress stream from the read interface of the delay memory 408.

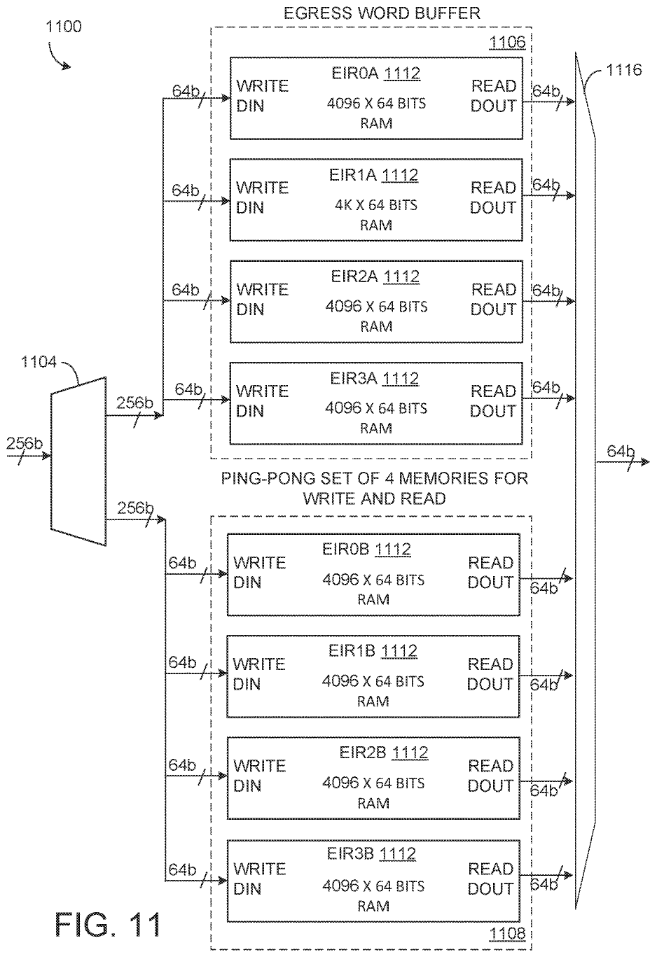

FIG. 11 illustrates an example of an egress word buffer 1100 that is employable to implement the egress word buffer 432 of FIG. 4. The egress word buffer 1100 receives an egress stream of length S symbols data words, such as the egress stream of data words provided from the delay memory 408 of FIG. 4 and/or the egress stream of S symbols data words provided by the delay memory convolutional interleaver 900 of FIG. 9A, the delay memory convolutional deinterleaver 950 of FIG. 9B, the delay memory block interleaver 1000 of FIG. 10A or the delay memory block deinterleaver 1050 of FIG. 10B. In some examples, multiple data words which correspond to the same interleaver row (S symbols) are read from the read interface of the delay memory 408 in a data burst operation to increase a throughput. For instance, in some examples, 8 words of 256-bit each (corresponding to a single interleaver row) are read from the read interface of the delay memory 408 to ensure that each read operation from the delay memory 408 read interface has 2048 bits comprising S symbols (e.g., a delay memory with a 64-bit wide interface using a burst length of 8 and block size of 4). In other examples, there may be more or less than 256-bits at the read interface of the delay memory 408.

The egress stream of 256-bit data words is provided to a demultiplexer 1104 that is controlled by a selection signal (not shown) from a controller (e.g., the controller 410 of FIG. 4). The demultiplexer 1104 is coupled to a first set of egress input RAMs 1106 or a second set of egress input RAMs 1108. The first set of egress input RAMs 1106 and the second set of egress input RAMs 1108 are formed of egress input RAMs 1112. The egress input RAMs 1112 of the first set of egress input RAMs 1106 (e.g., group A) are labeled EIR0A . . . EIR3A and the second set of egress input RAMs 1108 (e.g., group B) are labeled EIR0B . . . EIR3B. In the example illustrated, there are T equal to 4 egress input RAMs 1112 in the first set of egress input RAMs 1106 and the T equal to 4 egress input RAMs 1112 in the second set of egress input RAMs 1108. However, in other examples there are more or less egress input RAMs 1112 in the first set of egress input RAMs 1106 and the second set of egress input RAMs 1108.

For each 256-bit word, the demultiplexer 1104 is configured to contemporaneously write each 64-bits (R symbols) of each 256-bit input data word (e.g., in a de-concatenation operation) to each of the egress input RAMs 1112 of the first set of egress input RAMs 1106 or the second set of egress input RAMs 1108.

In the example illustrated, the egress input RAMs 1112 are RAM modules that hold 4096 64-bit words (e.g., 4096×64 bit RAM), but in other modules, other sizes are employable. The egress word buffer 1100 is configured in a ping-pong arrangement, such that each four (4) 64-bit words (e.g., a block of four sets of R symbols) are provided to the first set of egress input RAMs 1106 in sequence, S/4R times, until a block of S symbols have been provided for a given interleaver row. These operations are repeated N times, once for each interleaver row, until a total of NS symbols are provided. The egress word buffer 1100 then ping-pongs, such that the next block of NS symbols is provided in sequence to the second set of egress input RAMs 1108, continuing in alternating fashion. For example, 4 consecutive 64-bit words (4 sets of R symbols) of a given 256-bit data word are written contemporaneously to a first memory location (first address) of each of EIR0A, EIR1A, EIR2A and EIR3A of the first set of egress input RAMs 1106. Subsequently, a next 4 consecutive 64-bit words of a next 256-bit word are written contemporaneously to a second memory location (second address) of each of EIR0A, EIR1A, EIR2A and EIR3A of the first set of egress input RAMs 1106. This repeats S/4R times, providing S symbols, corresponding to one row of the N row interleaver. These operations are repeated N times, once for each interleaver row, until a total of NS symbols have been written to NS/4R memory locations. Subsequently, a next 4 consecutive 64-bit words of a next 256-bit word are written contemporaneously to a first memory location (first address) of each of EIR0B, EIR1B, EIR2B and EIR3B of the second set of egress input RAMs 1108. Subsequently, a next 4 consecutive 64-bits of a next 256-bit word are written contemporaneously to a second memory location (second address) of each of EIR0B, EIR1B, EIR2B and EIR3B of the second set of egress input RAMs 1108. This repeats S/4R times, providing S symbols, corresponding to one row of the N row interleaver. These operations are repeated N times, once for each interleaver row, until a total of NS symbols have been written to NS/4R memory locations. In this manner, each NS consecutive symbols are written to different sets of egress input RAMs 1106 and 1108. Stated differently, each 256-bit word input to the egress word buffer 1100 is broken into 4 64-bit words (4 sets of R symbols), and each 64-bit word (R symbols) is written to one of four egress input RAMs 1112, repeating NS/4R times until NS symbols are written to a given set of egress input RAMs.

The egress input RAMs 1112 store buffered 64-bit words (R symbols) in the manner explained. Additionally, the egress input RAMs 1112 of the first set of egress input RAMs 1106 output stored 64-bit words (R symbols) to a multiplexer 1116 that outputs an egress stream of 64-bit words (e.g., streams of R symbols, more generally). Specifically, a selection signal (not shown) from a controller (e.g., the controller 410 of FIG. 4) causes the multiplexer 1116 to sequentially output 64-bit words from the first set of egress input RAMs 1106. The sequence of symbols output from the first set of egress input RAMs 1106 is a first R symbols from each interleaver row, in sequence from row 0 to N, then a next R symbols from each interleaver row, in sequence from row 0 to N, repeating S/R times for a total of NS symbols. In one example, in which the first set of egress input RAMs 1106 is formed with T equal to 4 egress input RAMs 1112, the selection signal causes the multiplexer 1116 to select a first egress input RAM 1112 (EIR0A) for a sequence of N 64-bit words (NR symbols), next select a second egress input RAM 1112 (EIR1A) for a sequence of N 64-bit words (NR symbols), next select a third egress input RAM 1112 (EIR2A) for a sequence of N 64-bit words (NR symbols), continuing to select in sequence each up to the T^{th} egress input RAM 1112 (EIR3A) for N 64-bit words (NR symbols) each, for a total of NRT symbols. These operations are repeated S/RT times resulting in the output of a total of NS symbols from the first set of egress input RAMs 1106. The selection signal then causes the multiplexer 1116 to output 64-bit words from the second set of egress input RAMs 1108, selecting in sequence each egress input RAM 1112. The selection sequence is as described previously for each of the egress input RAMs 1112 of the first set of egress input RAMs 1106. The outputted 64-bit words are provided as the egress stream of 64-bit words.

In an alternative design, the ping-pong arrangement is avoided by controlling timing of writes from the delay memory to the egress word buffer 1100. In one example, with the set of egress input RAMs 1106 that includes T egress input RAMs 1112, the ping-pong is avoided as follows. Each group of RT symbols from demultiplexer 1104 is written contemporaneously to the T egress input RAMs 1112. Identify each group of RT symbols as including the {1^{st}, 2^{nd}, 3^{rd}, . . . , T^{th}} sets of R symbols, and identify the T egress input RAMs 1112 as the {1^{st}, 2^{nd}, 3^{rd}, . . . , T^{th}} egress input RAM 1112. A circular shift function (not shown) is included in the demultiplexer 1104 and is controlled by a control signal (not shown) such that each group of S symbols (S/RT groups of RT symbols) is connected to the T egress input RAMs 1112 in a selected order (e.g., 1^{st} R symbols written to the 1^{st} egress input RAM 1112, 2^{nd} R symbols written to the 2^{nd} egress input RAM 1112, continuing until the T^{th} R symbols written to the T^{th} egress input RAM 1112). The control signal then causes the selected order to change for the next group of S symbols (S/RT groups of RT symbols) by one circular shift (e.g., 1^{st} R symbols written to the 2^{nd} egress input RAM 1112, 2^{nd} R symbols written to the 3^{rd} egress input RAM 1112, continuing until the T−1^{th} R symbols written to the T^{th} egress input RAM 1112, and the T^{th} R symbols written to the 1^{st} egress input RAM 1112). The above operations repeat, selecting a next circular shift every S symbols (S/RT groups of RT symbols), and continues to repeat for each pass of NS symbols through the set of egress input RAMs 1106. Contemporaneously, one of each of the T egress input RAMs 1112, outputs sets of R symbols to the multiplexer 1116. In this case, instead of a ping-pong example of outputting R symbols N times from a given egress input RAM 1112 (NR symbols) before proceeding to the next egress input RAM 1112, in a non-ping-pong example read R symbols from each egress input RAM 1112 in the sequence {1^{st}, 2^{nd}, 3^{rd}, . . . , T^{th}} egress input RAM 1112 (for a total of RT symbols), repeat this sequence S/RT times (S symbols), next circular shift by one position the output order from the T egress input RAMs 1112 and read R symbols from each egress input RAM 1112 in the sequence {2^{nd}, 3^{rd}, . . . , T^{th}, 1^{st}}, repeat this sequence S/RT times (S symbols), continue these operations until the circular shift by one position results in the sequence {T^{th}, 1^{st}, 2^{nd}, . . . , T−1^{th}} and read R symbols from each egress input RAM 1112. At this point, a total of ST symbols have been output from the set of egress input RAMs 1106. The sequence of operations repeats a total of N/T times until NS symbols have been output from the set of egress input RAMs 1106. The process repeats for pass of NS symbols through the egress input RAMs 1106. In each instance of outputting R symbols from an egress input RAM 1112, those R symbols correspond to a single interleaver row which have been stored the longest and not previously output (oldest), and are in a sequence of interleaver rows from 0 to N−1. Each pass of NS symbols through the set of egress input RAMs 1106, the write locations follow the same sequence immediately subsequent to the locations being read in the last S/RT accesses of each egress input RAM 1112 (the locations of the previous S symbols output). Each pass through the set of egress input RAMs 1106, the read location sequence alternates between two patterns which implement the described output sequence.

Whether or not a ping-pong arrangement is employed, the example egress word buffer 1100 receives an egress stream of 256-bit words. In some examples, multiple words which correspond to the same interleaver row (S symbols) are read from the read interface of the delay memory in a data burst operation to increase a throughput. For instance, in some examples, 8 of the 256-bit words (corresponding to a single interleaver row) are read from the read interface of the delay memory to ensure that each read operation from the delay memory read interface has 2048 bits including S symbols (e.g., a delay memory with a 64-bit wide interface using a burst length of 8 and block size of 4).

Referring back to FIG. 4, the egress stream of length R symbol words (64 one-bit symbols, in some examples) is provided to an egress reorder symbols submodule 436. The egress reorder symbols submodule 436 receives a sequence of length Q of R symbol words corresponding to subsequent rows of the interleaver or deinterleaver. Each R symbol word is loaded into one of Q shift registers stepping through the Q Rows {k to k+Q−1}, such that each length Q sequence of R symbol words loads the number Q of length R symbol shift registers. This operation is executed in sequence for values of k=0, Q, 2Q, up to N−Q, corresponding to the previously described output sequence from the egress word buffer 432. The output sequence from the egress reorder symbols submodule 436 is a sequence of Q symbols, one symbol from each of the Q shift registers. The egress reorder symbols submodule 436 thus provides an egress stream of length Q symbols (e.g., 64 one-bit symbols in some examples), each symbol corresponding to a different interleaver or deinterleaver row.

More generally, the egress reorder symbols submodule 436 outputs the egress stream of length Q symbols based on the egress stream of symbols having the length R. The egress reorder symbols submodule 436 stores symbols of the egress stream of symbols having the length R output by the egress word buffer in shift registers, and there are the Q number of shift registers in the egress reorder symbols submodule 436. The egress reorder symbols submodule 436 is configured such that each shift register in the egress reorder symbols submodule 436 stores each R symbol subset of the egress stream of length R symbols, and the Q shift registers of the egress reorder symbols submodule 436 each output one symbol for the egress stream of length Q symbols.

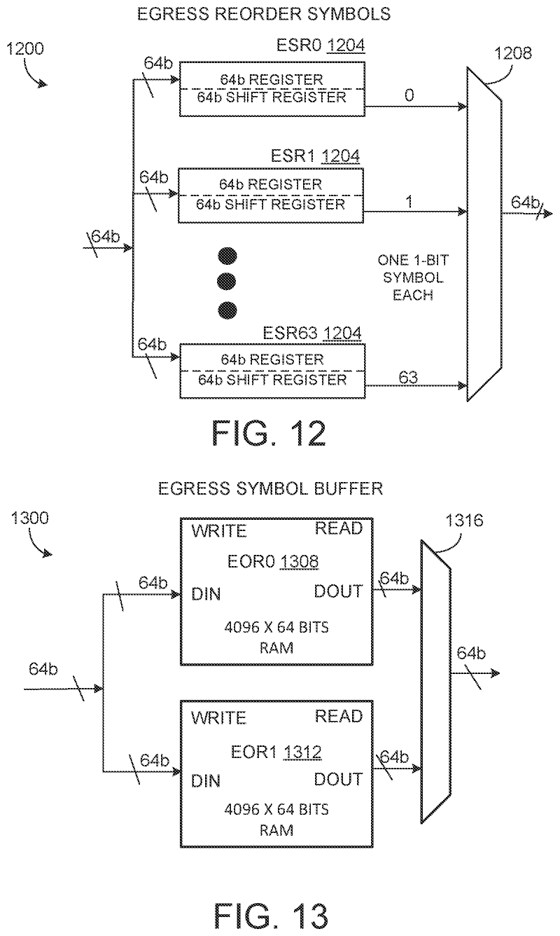

FIG. 12 illustrates an egress reorder symbols submodule 1200 that is employable to implement the egress reorder symbols submodule 436 of FIG. 4. The reorder symbols submodule 1200 includes Q equal to 64 egress shift registers 1204, labeled ESR0 . . . ESR63, each of length R equal to 64 one-bit symbols. More generally, the reorder symbols submodule 1200 includes Q number of egress shift registers 1204 for length R symbols.

The egress shift registers 1204 are arranged to receive an egress stream of 64-bit words (e.g., an egress stream of length R symbols) from an egress word buffer, such as the egress word buffer 1100 of FIG. 11 and/or the egress word buffer 432 of FIG. 4. Each such 64-bit word is written to a given one of the 64 egress shift registers 1204. For example, the given 64-bit word can be provided to each of the 64 egress shift registers 1204, but only a selected egress shift register 1204 is write enabled (the remaining 63 egress shift registers 1204 are set to read-only), such that the given 64-bit word is written to the selected egress shift register 1204. The selected egress shift registers 1204 changes to a next egress shift register 1204, and the next 64-bit word is written to the (next) selected egress shift registers 1204 in a similar manner. For instance, a first 64-bit word (word 0) of the incoming 64-bit words can be written to a first egress shift register 1204 (ESR0) and a second 64-bit word (word 1) of the 64-bit words can be written to a second egress shift register 1204 (ESR1) . . . and a 64th 64-bit word (word 63) can be written to the 64th egress shift registers 1204 (ESR63), and the process repeats.

The each egress shift register 1204 is configured to store (queue) 64-bits (length R symbols, more generally). Responsive to Q egress shift registers 1204 storing the 64-bit words (R number of symbols, more generally), each 64-bits are transferred to an output shift register of each egress shift register 1204. Responsive to shifting each 64-bits to each output shift register, the egress shift registers 1204 can store a next length Q set of 64-bit words in the egress shift registers 1204.

The 64 egress shift registers 1204 (ISR0 . . . ISR63) output one bit at a time (one-bit symbols in this example) to a multiplexer 1208. The multiplexer 1208 outputs 64 (Q number, more generally) bits to provide 64-bit words (length Q number of one-bit symbols, more generally). Moreover, because the egress shift registers 1204 each provide a single bit of each 64-bit word (R one-bit symbol word, more generally), the order of the 64 one-bit symbols output by the multiplexer 1208 is different than the 64 one-bit symbols provided to the egress shift registers 1204. The multiplexer 1208 outputs an egress stream of 64-bit words (e.g., an egress stream of length Q one-bit symbols, more generally). In other examples, symbols of other than one-bit are reordered by the number Q set of egress shift registers 1204, each of the Q egress shift registers 1204 store R symbols and provide a sequence of one symbol each to the multiplexer 1208 which outputs Q symbols.

Referring back to FIG. 4, as noted, the egress reorder symbols submodule 436 outputs an egress stream of length Q symbols. This egress stream of length Q symbols is provided to an egress symbol buffer 440. The egress symbol buffer 440 writes one word of length Q symbols at a time to a buffer memory. The egress symbol buffer 440 writes words of length Q symbols from the egress stream of length Q symbols R number of times (QR symbols) and then repeats N/Q times (NR symbols). The egress symbol buffer 440 outputs an egress buffered length Q symbol stream that is provided along Q paths. More generally, the egress symbol buffer is configured to buffer the egress stream of length Q symbols to output the egress stream of buffered length Q symbols through Q of parallel paths.

The egress symbol buffer 440 has a ping-pong memory structure that enables buffering of the length Q symbol words in the egress Q symbol stream with an unknown burstiness. In particular, the egress symbol buffer 440 includes input RAM modules. In the ping-pong configuration a first input RAM module stores a first set of symbols of the egress stream of length Q symbol words contemporaneously with a second input RAM module outputting a second set of symbols of the egress stream of length Q symbol words for the egress stream of buffered length Q symbol words. In examples where the egress length Q symbol stream data rate variation is limited or controlled by an output buffer (e.g., a first in first out (FIFO) buffer), the ping-pong memory structure can be avoided.

FIG. 13 illustrates an example of egress symbol buffer 1300 that is employable to implement the egress symbol buffer 440 of FIG. 1. Operations of the egress symbol buffer 1300 are controlled by a controller, such as the controller 410 of FIG. 1. The egress symbol buffer 1300 includes a first egress output RAM module 1308 (labeled “EOR0” in FIG. 13) and a second egress output RAM module 1312 (labeled “EOR1” in FIG. 13). In the example illustrated, the first egress output RAM module 1308 and the second egress output RAM module 1312 are RAM modules each hold 4096 64-bit words (e.g., 4096×64 bit RAM), but in other modules, other sizes are employable. The egress symbol buffer 1300 is configured in a ping-pong arrangement, such that 64-bit words (e.g., a block of Q symbols) are written to the first egress output RAM module 1308 and the second egress output RAM module 1312 in alternating fashion, such that NR/Q consecutive blocks of Q symbols (64-bit words) are written to a first egress input RAM module 1308, then NR/Q consecutive blocks of Q symbols (64-bit words) are written to a second egress input RAM module 1312. To execute this operation, a selected egress output RAM module (the first egress output RAM module 1308 or the second egress output RAM module 1312) is set to write enable and the remaining (other) egress output RAM module is set to read-only for each NR/Q blocks of Q symbols (a total of NR symbols) to be written to the selected egress output RAM module. The selected egress output RAM module changes, and a next sequence of NR/Q blocks of Q symbols (NR symbols) is written to the newly selected egress output RAM module.

The egress symbol buffer 1300 includes a multiplexer 1316 (alternatively referred to as a one-to-two switch) that receives a 64-bit parallel signal from the first egress output RAM module 1308 and the second egress output RAM module 1312 (e.g., length Q symbols, more generally) at an input port. The multiplexer 1316 has a selection signal (not shown) controlled by the controller (e.g., the controller 410 of FIG. 4) to alternate reading from the first egress output RAM module 1308 and the second egress output RAM module 1312 causing the multiplexer 1316 to output a buffered egress 64-bit word symbol stream (e.g., an egress buffered length Q symbol stream, more generally) wherein the order of the symbols in the 64-bit words match an order of the symbols in the 64-bit words provided to the egress symbol buffer 1300, however the order of the 64-bit words is reordered. The order of the 64-bit words input to the egress symbol buffer 1300 is each 64-bit word (Q symbols) corresponds to set of interleaver rows k to k+Q−1 repeating each value of k R times before advancing in the sequence of k=0, Q, 2Q, up to N−Q (NR total symbols). The order of the 64-bit words output from the egress symbol buffer 1300 is one 64-bit word (Q symbols) corresponding to each set of interleaver rows k to k+Q−1 for k=0, Q, 2Q, up to N−Q, repeating the sequence of values of k R times (NR total symbols).

In an alternative design, the egress symbol buffer 1300 can be implemented with a single egress output RAM module, wherein write and read addresses are swapped for each pass of data transfer through the memory module. In this manner, the read order is sequential and the write order is stepped for one read and write pass through the egress symbol buffer 1300, then the read order is stepped and the write order is sequential for the next pass through the egress symbol buffer 1300, alternating each pass. In either situation, the egress symbol buffer 1300 provides the reordered buffered egress 64-bit symbol stream (e.g., the egress buffered length Q symbol stream, more generally).

Referring back to FIG. 4, as demonstrated, the egress symbol buffer 440 outputs the egress buffered length Q symbol stream. The egress buffered length Q symbol stream is provided to a parallel to serial interface 444.

The parallel to serial interface 444 converts length Q symbol output into a one symbol output. For example, the parallel to serial interface 444 could be configured to convert a 64-bit word corresponding to Q symbols into a 4-lane signal of serial data, such as used for some Ethernet interfaces. Thus, in such a situation, Q would be equal to 64, and there would be a sequence of one-bit symbols output by the parallel to serial interface 444. Accordingly, the parallel to serial interface 444 provides an egress stream of serial symbols along 4 lanes (or other number of lanes). More generally, the parallel to serial interface 444 serializes the egress stream of buffered length Q symbols to provide an interleaved data stream of serial data as an egress stream of serial symbols. This egress stream of serial symbols is the output of the data rearranger 400, and can be provided to an external system, such as a transmitter or an error corrector.

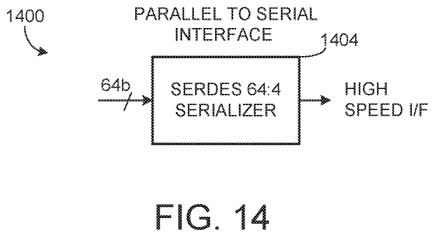

FIG. 14 illustrates an example of a parallel to serial interface 1400 that is employable to implement the parallel to serial interface 444 of FIG. 4. The parallel to serial interface 1400 includes a 64:4 SERDES (serial/deserializer) seralizer 1404 that converts a 64-bit parallel signal into a serial signal provided for a 4-lane high speed interface (labeled in FIG. 14 as HIGH SPEED I/F) into a 64-bit parallel signal. For example, the serial signal could be a 1 bit per symbol signal that is provided at a bursty data rate of 32 Gbps (gigabits per second).

Referring back to FIG. 4, as demonstrated, the ingress module 404 and the delay memory 408 rearrange the input data into format (e.g., size and rate) consumable by the delay memory 408 (e.g., SDRAM) for a convolutional interleaver or a convolutional deinterleaver (to implement the first example) or for a block interleaver or a block deinterleaver (to implement the second example). Accordingly, the delay memory 408 can be relatively large, such as 1 GB (gigabyte) or more (e.g., 8 GB), without sacrificing speed of a data transfer.

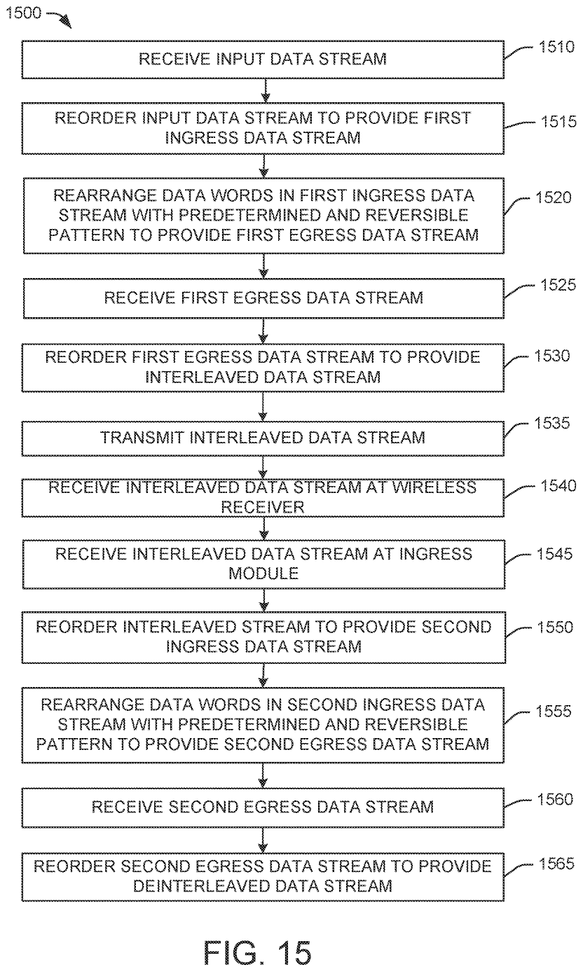

In view of the foregoing structural and functional features described above, example methods will be better appreciated with reference to FIG. 15. While, for purposes of simplicity of explanation, the example methods of FIG. 15 are shown and described as executing serially, it is to be understood and appreciated that the present examples are not limited by the illustrated order, as some actions could in other examples occur in different orders and/or concurrently (e.g., in parallel) from that shown and described herein. Moreover, it is not necessary that all described actions be performed to implement a method.

FIG. 15 illustrates a flowchart of an example method 1500 for wirelessly communicating data over a data link. The method 1500 can be executed for example, by the communication system 100 of FIG. 1. At block 1510, an interleaver (e.g., the interleaver 136 of FIG. 1) receives an input data stream. The input data stream is a stream of codewords formed from a concatenation (or another type of combination) of input data and error correction codes. At block 1515, an ingress module (e.g., the ingress module 144 of FIG. 1) of the interleaver, reorders the input data stream to provide an ingress stream of data words to a write interface of delay memory of the interleaver at an interleaver size and rate that satisfies an interleaver write threshold. The interleaver write threshold defines a portion (e.g., about 50% or more) of a predetermined size and rate for the delay memory of the interleaver.

In some situations, the method 1500 is employable to implement the first example. In this situation, the interleaver is a convolutional interleaver. In other situations, the method 1500 is employable to implement the second example. In these situations, the interleaver is a block interleaver.

At block 1520, a controller of the interleaver (e.g., the controller 410 of FIG. 4) controls operations of the delay memory, to cause the delay memory to store the data words of the ingress stream of data words received at the write interface as blocks of data in the delay memory. The blocks of data include a set number of rows, and the data words received at the write interface of the delay memory are rearranged in a predefined and reversible pattern to provide a first egress stream of data words at a read interface of the delay memory have a different order than the data words of the ingress stream of data words received at the write interface of the delay memory.

At block 1525, an egress module (e.g., the egress module 148 of FIG. 1) of the interleaver receives the first egress stream of data words from the delay memory at an interleaver size and rate that satisfies an interleaver read threshold. The interleaver read threshold defines a portion of the predetermined size and rate of the delay memory of the interleaver (e.g., about 50% or more) and outputs an interleaved data stream. At block 1530, the egress module of the interleaver reorders the first egress stream of data words to provide an interleaved data stream. At block 1535, a transmitter (e.g., the transmitter 116 of FIG. 1) transmits the interleaved data stream received from the egress module into free space.

At block 1540, a wireless receiver (e.g., the receiver 120 of FIG. 1) receives, the interleaved data stream transmitted through free space. At block 1545, a deinterleaver (e.g., the deinterleaver 138 of FIG. 1) receives the interleaved data stream from the wireless receiver. At block 1550, an ingress module of the deinterleaver (e.g., the egress module 160 of FIG. 1) reorders the interleaved data stream to provide a second ingress stream of data words based on the interleaved data stream to a write interface of delay memory of the deinterleaver at a deinterleaver size and rate that satisfies a deinterleaver write threshold. The deinterleaver write threshold defines a portion of the predetermined size and rate (e.g., about 50% or more) of the delay memory of the deinterleaver.

At block 1555, a controller (e.g., the controller 410 of FIG. 4) controls operations of the delay memory of the deinterleaver causing the delay memory of the deinterleaver to store the data words of the second ingress stream of data words received at the write interface as blocks of data. The blocks of data have a set number of rows, and the data words received at the input interface of the delay memory of the deinterleaver are rearranged to reverse the predefined pattern, such that data words of a second egress data stream provided at the read interface of the delay memory of the deinterleaver have a different order than data words of the second ingress stream of data words received at the write interface of the delay memory of the deinterleaver.

At block 1560, an egress module (e.g., the egress module 160 of FIG. 1) of the deinterleaver receives a second egress stream of data words from the delay memory of the deinterleaver at a deinterleaver size and rate that satisfies a deinterleaver read threshold. The deinterleaver read threshold defines a portion of the predetermined size and rate of the delay memory of the deinterleaver (e.g., about 50% or more). At block 1565, the egress module of the deinterleaver outputs a deinterleaved data stream having codewords having data and error correction codes based on the second egress stream of data words. The error correction codes of the codewords enable an error corrector (e.g., the error corrector 139 of FIG. 1) to detect and correct errors in the deinterleaved data stream to provide output data that matches the input data.

What have been described above are examples. It is, of course, not possible to describe every conceivable combination of components or methodologies, but one of ordinary skill in the art will recognize that many further combinations and permutations are possible. Accordingly, the disclosure is intended to embrace all such alterations, modifications, and variations that fall within the scope of this application, including the appended claims. As used herein, the term “includes” means includes but not limited to, the term “including” means including but not limited to. The term “based on” means based at least in part on. Additionally, where the disclosure or claims recite “a,” “an,” “a first,” or “another” element, or the equivalent thereof, it should be interpreted to include one or more than one such element, neither requiring nor excluding two or more such elements.

What is claimed is:

1. A wireless transceiver comprising:
an interleaver that receives an input data stream comprising codewords formed of a combination of input data and error correction codes, the interleaver comprising:
delay memory with a write interface tuned to receive data words at a write interface that have a predetermined size and rate and a read interface tuned to provides data words at the predetermined size and rate;
an ingress module that reorders the input data stream to provide an ingress stream of data words to the write interface of the delay memory at an interleaver size and rate that satisfies an interleaver write threshold that defines a portion of the predetermined size and rate of the delay memory of the interleaver;
an egress module that receives an egress stream of data words from the delay memory at an interleaver size and rate that satisfies an interleaver read threshold that defines a portion of the predetermined size and rate of the delay memory of the interleaver and outputs an interleaved data stream; and
a memory controller that controls operations of the delay memory, wherein the memory controller causes the delay memory to store the data words of the ingress stream of data words received at the write interface as blocks of data in the delay memory, the blocks of data comprising a set number of rows, and the data words received at the write interface of the delay memory are rearranged in a predefined and reversible pattern, such that data words of the egress stream of data words provided at the read interface of the delay memory have a different order than the data words of the ingress stream of data words received at the write interface of the delay memory; and
a wireless transmitter that transmits the interleaved data stream received from the egress module into free space.

2. The wireless transceiver of claim 1, wherein the interleaver is a convolutional interleaver, such that rows of the blocks of data in the delay memory have increasing lengths, wherein the increasing lengths of the rows defines a set delay added between data words consecutively received at the write interface and that are provided at the read interface.

3. The wireless transceiver of claim 1, wherein the interleaver is a block interleaver, such that rows of the blocks of data in the delay memory have a same length, wherein the length of the rows defines a set delay added between data words consecutively received at the write interface and that are provided at the read interface.

4. The wireless transceiver of claim 1, wherein the interleaved data stream is a first interleaved data stream, the ingress stream of data words is a first ingress stream of data words and the egress stream of data words is a first egress stream of data words, the wireless transceiver further comprising:
a wireless receiver that receives a second interleaved data stream from free space;
a deinterleaver that receives the second interleaved data stream, the second interleaved data stream comprising codewords formed with a combination of input data and the error correction codes, the deinterleaver comprising:
delay memory with a write interface tuned to receive data words at the predetermined size and rate and a read interface tuned to provide data words at the predetermined size and rate;
an ingress module that reorders the second interleaved data stream to provide a second ingress stream of data words to the write interface of the delay memory at a deinterleaver size and rate that satisfies a deinterleaver write threshold that defines a portion of the predetermined size and rate of the delay memory of the deinterleaver the predetermined size and rate;
an egress module that receives a second egress stream of data words from the delay memory of the deinterleaver at a deinterleaver size and rate that satisfies a deinterleaver read threshold that defines a portion of the predetermined size and rate of the delay memory of the deinterleaver and outputs a deinterleaved data stream; and
a memory controller that controls operations of the delay memory of the deinterleaver, wherein the memory controller causes the delay memory to store the data words of the second ingress stream of data words received at the write interface as blocks of data, the blocks of data comprising a set number of rows, and the data words received at the write interface of the delay memory of the deinterleaver are rearranged to reverse a predefined pattern, such that data words of the second egress stream of data words provided at the read interface of the delay memory of the deinterleaver have a different order than data words of the second ingress stream of data words received at the write interface of the delay memory of the deinterleaver; and
an error corrector that detects and corrects errors in the deinterleaved data stream based on the error correction codes of the deinterleaved data stream.

5. The wireless transceiver of claim 1, wherein the ingress module and the egress module of the interleaver are implemented on an IC (integrated circuit) chip.

6. The wireless transceiver of claim 5, wherein the delay memory of the interleaver and the interleaver is an SDRAM (synchronous dynamic random-access memory) module with a capacity of at least 1 gigabyte.

7. The wireless transceiver of claim 1, wherein the ingress module comprises:
a serial to parallel interface that deserializes symbols in the input data stream to provide an ingress stream of symbols having a first length through a first number of parallel paths;
an ingress symbol buffer that buffers the ingress stream of symbols having the first length to output a buffered ingress stream of symbols having the first length;
an ingress reorder symbols submodule that stores the symbols of the ingress stream of symbols having the first length output by the ingress symbol buffer in shift registers, wherein there are the first number of shift registers, such that one bit of a given symbol of the ingress stream of symbols having the first length is stored in each of the shift registers, and the shift registers output an ingress stream of symbols having a second length; and
an ingress word buffer that receives the ingress stream of symbols having the second length from the shift registers of the ingress reorder symbols submodule and concatenates multiple symbols of the ingress stream of symbols of the second length to provide the ingress stream of data words to the write interface of the delay memory.

8. The wireless transceiver of claim 7, wherein the ingress symbol buffer comprises input RAM modules arranged in a ping-pong configuration, such that a first input RAM module of the input RAM modules stores a first set of symbols of the ingress stream of symbols having the first length contemporaneously with a second input RAM module of the input RAM modules outputting a second set of symbols of the ingress stream of symbols having the first length for the buffered ingress stream of symbols having the first length.

9. The wireless transceiver of claim 7, wherein the ingress word buffer comprises output RAM modules arranged in a ping-pong configuration, such that a first set of output RAM modules of the output RAM modules stores a first set of the symbols having the second length contemporaneously with a second set of output RAM modules of the output RAM modules outputting a second set of symbols of the ingress stream of symbols having the second length for the ingress stream of data words.

10. The wireless transceiver of claim 7, wherein the ingress symbol buffer comprises an input RAM module write and read addresses that are swapped for each pass of data transfer through the input RAM module, such a read order is sequential and a write order is stepped for one read and write pass through the ingress symbol buffer, and the read order and the write order are swapped for a next pass.

11. The wireless transceiver of claim 7, wherein the ingress word buffer comprises output RAM modules and a multiplexer and the memory controller controls timing of writes from the ingress reorder symbols submodule causes writing symbols across the output RAM modules, with a circular shift after every set number of symbols, ensuring an orderly output of symbols to the multiplexer of the ingress word buffer in a repeating pattern.

12. The wireless transceiver of claim 7, wherein the egress module comprises:
an egress word buffer that receives the egress stream of data words from the read interface of the delay memory and separates each data word of the egress stream of data words to provide an egress stream of symbols having the second length;
an egress reorder symbols submodule that outputs an egress stream of symbols of the first length based on the egress stream of symbols having the second length, wherein the egress reorder symbols submodule stores symbols of the egress stream of symbols having the second length output by the egress word buffer in shift registers, and there are the first number of shift registers in the egress reorder symbols submodule, such that each shift registers in the egress reorder symbols submodule stores a subset of the symbols in the egress stream of symbols having the second length, and the shift registers of the egress reorder symbols submodule each output one symbol for the egress stream of symbols having the first length;
an egress symbol buffer that buffers the egress stream of symbols having the first length to output an egress stream of buffered symbols having the first length through a first number of parallel paths; and
a parallel to serial interface that serializes the egress stream of buffered symbols to provide the interleaved data stream.

13. The wireless transceiver of claim 12, wherein the egress word buffer comprises input RAM modules arranged in a ping-pong configuration, such that a first set of input RAM modules of the input RAM modules stores a first set of the symbols having the second length contemporaneously with a second set of input RAM modules of the input RAM modules outputting a second set of symbols of the egress stream of symbols having the second length for the egress stream of symbols having the second length.

14. The wireless transceiver of claim 12, wherein the egress symbol buffer comprises output RAM modules arranged in a ping-pong configuration, such that a first output RAM module of the output RAM modules stores a first set of symbols of the egress stream of symbols having the first length contemporaneously with a second output RAM module of the output RAM modules outputting a second set of symbols of the egress stream of symbols having the first length for the egress stream of buffered symbols having the first length.

15. The wireless transceiver of claim 12, wherein the egress word buffer comprises input RAM modules and a demultiplexer, and the memory controller controls a timing of symbol writes from the delay memory to the egress word buffer by writing groups of symbols from the demultiplexer of the egress word buffer the input RAM modules, and the timing of signal writes incorporates a circular shift function that changes an order of symbol writes to the input RAM modules after a predetermined number of symbols have been written.

16. The wireless transceiver of claim 12, and the egress symbol buffer comprises an output RAM module and write and read addresses are swapped for each pass of data transfer through the output RAM module, such a read order is sequential and a write order is stepped for one read and write pass through the egress symbol buffer, and the read order and the write order are swapped for a next pass.

17. A system for wirelessly transmitting data over a link, the system comprising:
a first transceiver comprising:
an error correction inserter that inserts error correction codes into a stream of input data to provide a stream of codewords comprising a combination of data in the stream of input data and the error correction codes;
an interleaver that receives the stream of codewords, the interleaver comprising:
delay memory with a write interface tuned to receive data words at a write interface that have a predetermined size and rate and a read interface tuned to provides data words at the predetermined size and rate;
an ingress module that reorders the stream of codewords to provide a first ingress stream of data words to the write interface of the delay memory of the interleaver at an interleaver size and rate that satisfies an interleaver write threshold that defines a portion of the predetermined size and rate of the delay memory of the interleaver;
an egress module that receives a first egress stream of data words from the delay memory of the interleaver at an interleaver size and rate that satisfies an interleaver read threshold that defines a portion of the predetermined size and rate of the delay memory of the interleaver and outputs an interleaved data stream; and
a memory controller that controls operations of the delay memory of the interleaver, wherein the memory controller causes the delay memory to store the data words of the first ingress stream of data words received at the write interface as blocks of data in the delay memory of the interleaver, the blocks of data comprising a set number of rows, and the data words of the first ingress stream of data words received at the write interface of the delay memory are rearranged in a predefined and reversible pattern, such that data words of the first egress stream of data words provided at the read interface of the delay memory have a different order than the data words of the first ingress stream of data words received at the write interface of the delay memory; and
a wireless transmitter that transmits the interleaved data stream received from the egress module over the link; and
a second transceiver comprising:
a wireless receiver that receives the interleaved data stream transmitted over the link;
a deinterleaver that receives the interleaved data stream from the wireless receiver, the deinterleaver comprising:
delay memory with a write interface tuned to receive data words at the predetermined size and rate and a read interface tuned to provide data words at the predetermined size and rate;
an ingress module that reorders the interleaved data stream to provide a second ingress stream of data words based on the interleaved data stream to the write interface of the delay memory of the deinterleaver at a deinterleaver size and rate that satisfies a deinterleaver write threshold that defines a portion of the predetermined size and rate of the delay memory of the deinterleaver;
an egress module that receives a second egress stream of data words from the delay memory of the deinterleaver at a deinterleaver size and rate that satisfies a deinterleaver read threshold that defines a portion of the predetermined size and rate of the delay memory of the deinterleaver and outputs a deinterleaved data stream having codewords comprising data and error correction codes based on the second egress stream of data words; and
a memory controller that controls operations of the delay memory of the deinterleaver, wherein the memory controller causes the delay memory of the deinterleaver to store the data words of the second ingress stream of data words received at the write interface as blocks of data, the blocks of data comprising the set number of rows, and the data words received at the write interface of the delay memory of the deinterleaver are rearranged to reverse the predefined and reversible pattern, such that data words of the second egress stream of data words provided at the read interface of the delay memory of the deinterleaver have a different order than data words of the second ingress stream of data words received at the write interface of the delay memory of the deinterleaver; and
an error corrector that detects and corrects errors in the deinterleaved data stream based on the error correction codes of the deinterleaved data stream to provide a stream of output data, such that the stream of output data matches the stream of input data.

18. The system of claim 17, wherein:
the interleaver is a convolutional interleaver, such that rows of the blocks of data in the delay memory of the interleaver have increasing lengths;
the increasing lengths of the rows of the interleaver defines a set delay added between data words consecutively received at the write interface of delay memory of the interleaver and that are provided at the read interface of the delay memory of the interleaver;
the deinterleaver is a convolutional deinterleaver, such that the rows of the blocks of data in the delay memory of the deinterleaver have decreasing lengths; and
the decreasing lengths of the rows of the deinterleaver defines a set delay added between data words consecutively received at the write interface of the delay memory of the deinterleaver and that are provided at the read interface of the deinterleaver.

19. A method for wirelessly communicating data over a data link, the method comprising:
receiving, by an interleaver, an input data stream comprising codewords formed with a combination of input data and error correction codes;
reordering, by an ingress module of the interleaver, the input data stream to provide an ingress stream of data words to a write interface of delay memory of the interleaver at an interleaver size and rate that satisfies an interleaver write threshold that defines a portion of a predetermined size and rate for the delay memory of the interleaver;
controlling, by a controller of the interleaver, operations of the delay memory, to cause the delay memory to store the data words of the ingress stream of data words received at the write interface as blocks of data in the delay memory, wherein the blocks of data comprises a set number of rows, and the data words received at the write interface of the delay memory are rearranged in a predefined and reversible pattern to provide an egress stream of data words at an read interface of the delay memory that have a different order than the data words of the ingress stream of data words received at the write interface of the delay memory;
receiving, at an egress module of the interleaver, an egress stream of data words from the delay memory at an interleaver size and rate that satisfies an interleaver read threshold that defines a portion of the predetermined size and rate of the delay memory of the interleaver and outputs an interleaved data stream;
reordering, by an egress module of the interleaver, the egress stream of data words to provide an interleaved data stream; and
transmitting, by a transmitter, the interleaved data stream received from the egress module into free space.

20. The method of claim 19, wherein the ingress stream of data words is a first ingress stream of data words, and the egress stream of data words is a first egress stream of data words, the method further comprising:
receiving, by a wireless receiver, the interleaved data stream transmitted through free space;
receiving, by a deinterleaver, the interleaved data stream from the wireless receiver;
reordering, by an ingress module of the deinterleaver the interleaved data stream to provide a second ingress stream of data words based on the interleaved data stream to a write interface of delay memory of the deinterleaver at a deinterleaver size and rate that satisfies write threshold that defines a portion of the predetermined size and rate of the delay memory of the deinterleaver;
controlling, by a controller of the deinterleaver, operations of the delay memory of the deinterleaver causing the delay memory of the deinterleaver to store the data words of the second ingress stream of data words received at the write interface as blocks of data, wherein the blocks of data comprises the set number of rows, and the data words received at the write interface of the delay memory of the deinterleaver are rearranged to reverse the predefined pattern, such that data words of a second egress stream of data words provided at the read interface of the delay memory of the deinterleaver have a different order than data words of the second ingress stream of data words received at the write interface of the delay memory of the deinterleaver;
receiving, by an egress module of the deinterleaver, a second egress stream of data words from the delay memory of the deinterleaver at a deinterleaver size and rate that satisfies a deinterleaver read threshold that defines a portion of the predetermined size and rate of the delay memory of the deinterleaver; and
outputting, by the egress module of the deinterleaver, a deinterleaved data stream having codewords comprising data and error correction codes based on the second egress stream of data words.
